(19) United States
(12) Patent Application Publication
(10) Pub. No.: US 2025/0374628 A1
(43) Pub. Date: Dec. 4, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Jia-Chuan YOU, Taoyuan City (TW); Chia-Hao CHANG, Hsinchu City (TW); Kuo-Cheng CHIANG, Zhubei City (TW); Chih-Hao WANG, Baoshan Township (TW)

(21) Appl. No.: 18/731,829

(22) Filed: Jun. 3, 2024

(51) Int. Cl. H01L 29/66; H01L 21/28; H01L 27/088; H01L 29/06; H01L 29/423; H01L 29/775; H01L 29/786

(52) U.S. Cl. CPC H10D 64/017; H01L 21/28141; H10D 30/014; H10D 30/43; H10D 30/6735; H10D 30/6757; H10D 62/121; H10D 84/83

(57) ABSTRACT

A method for forming a semiconductor structure is provided. The method includes forming an isolation structure between a first active region and a second active region, forming a dummy gate structure across channel regions of the first active region and the second active region, patterning the dummy gate structure to form a cut opening corresponding to the isolation structure, forming a wall structure in the cut opening, removing the dummy gate structure to form a gate trench, forming a gate stack in the gate trench, and forming a first gate-cut structure through the wall structure.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with related complementary metal-oxide-semiconductor (CMOS) processes, and their structure allows them to be aggressively scaled-down while maintaining gate control and mitigating SCEs. GAA devices provide a channel in a silicon nanowire/nanosheet. However, integration of fabrication of the GAA features around the nanowire/nanosheet can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A, 1A-1, 1A-2 and 1A-3 are schematic views illustrating the formation a semiconductor structure at one of the intermediate stages, in accordance with some embodiments.

FIGS. 1B-1, 1B-2 and 1B-3 are schematic views illustrating the formation a semiconductor structure at one of the intermediate stages, in accordance with some embodiments.

FIGS. 1C, 1C-1, 1C-2 and 1C-3 are schematic views illustrating the formation a semiconductor structure at one of the intermediate stages, in accordance with some embodiments.

FIGS. 1D, 1D-1, 1D-2 and 1D-3 are schematic views illustrating the formation a semiconductor structure at one of the intermediate stages, in accordance with some embodiments.

FIGS. 1E, 1E-1, 1E-2 and 1E-3 are schematic views illustrating the formation a semiconductor structure at one of the intermediate stages, in accordance with some embodiments.

FIGS. 1F and 1F-1 are schematic views illustrating the formation a semiconductor structure at one of the intermediate stages, in accordance with some embodiments.

FIGS. 1G, 1G-1, 1G-2 and 1G-3 are schematic views illustrating the formation a semiconductor structure at one of the intermediate stages, in accordance with some embodiments.

FIGS. 1H, 1H-1, 1H-2 and 1H-3 are schematic views illustrating the formation a semiconductor structure at one of the intermediate stages, in accordance with some embodiments.

FIGS. 1I, 1I-1, 1I-2 and 1I-3 are schematic views illustrating the formation a semiconductor structure at one of the intermediate stages, in accordance with some embodiments.

FIGS. 2A and 2B are top views illustrating the formation a semiconductor structure at various intermediate stages, in accordance with some embodiments.

FIGS. 3A, 3B and 3C are top views illustrating the formation a semiconductor structure at various intermediate stages, in accordance with some embodiments.

FIG. 4A is a schematic view illustrate the formation a semiconductor structure at one of the intermediate stages, in accordance with some embodiments.

FIGS. 4B and 4B-1 are schematic views illustrating the formation a semiconductor structure at one of the intermediate stages, in accordance with some embodiments.

FIGS. 4C and 4C-1 are schematic views illustrating the formation a semiconductor structure at one of the intermediate stages, in accordance with some embodiments.

FIGS. 4D and 4D-1 are schematic views illustrating the formation a semiconductor structure at one of the intermediate stages, in accordance with some embodiments.

FIGS. 4E and 4E-1 are schematic views illustrating the formation a semiconductor structure at one of the intermediate stages, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The method for forming the semiconductor structure may include forming a wall structure through a dummy gate structure, replacing the dummy gate structure with a gate stack, and forming a gate-cut structure through the wall structure. The wall structure may be helpful in reducing the total cell parasitic capacitance, and the gate-cut structure may ensure that the gate stack is completely cut off. Therefore, the performance and reliability of the resulting semiconductor device may be improved.

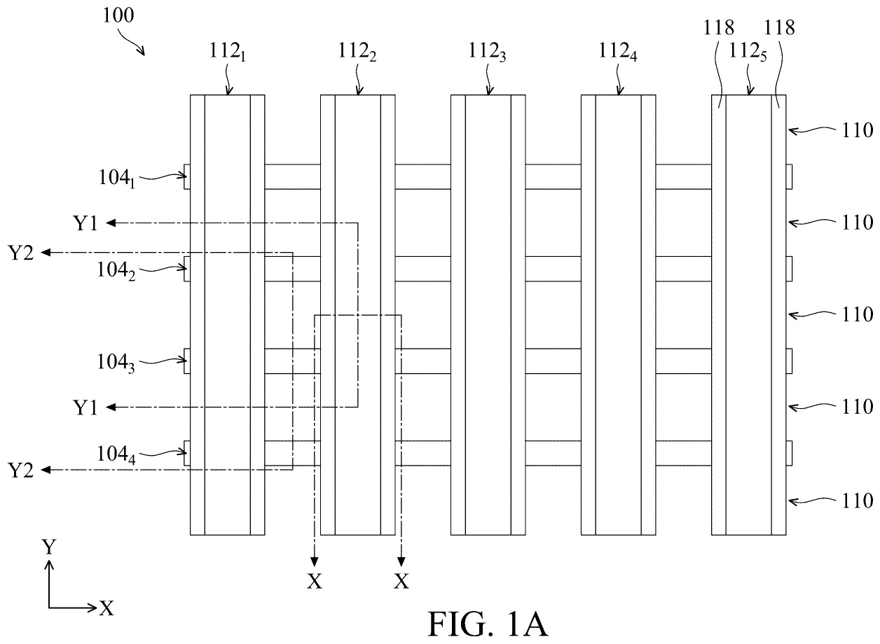

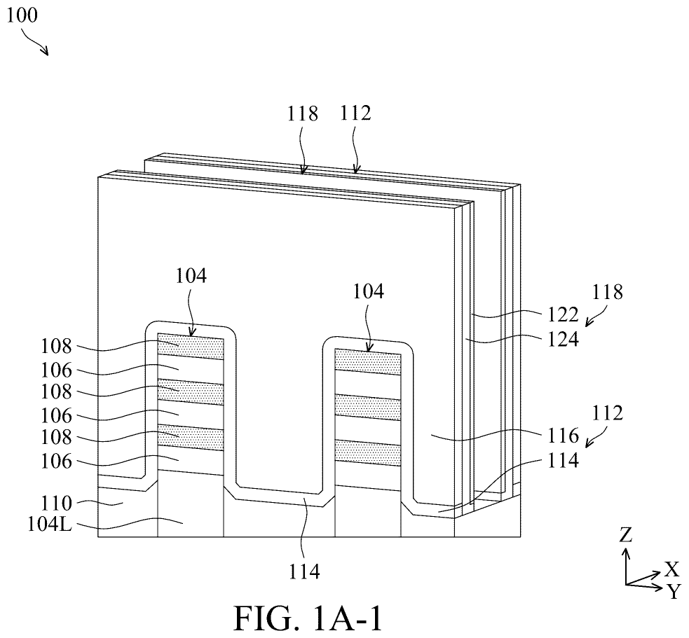

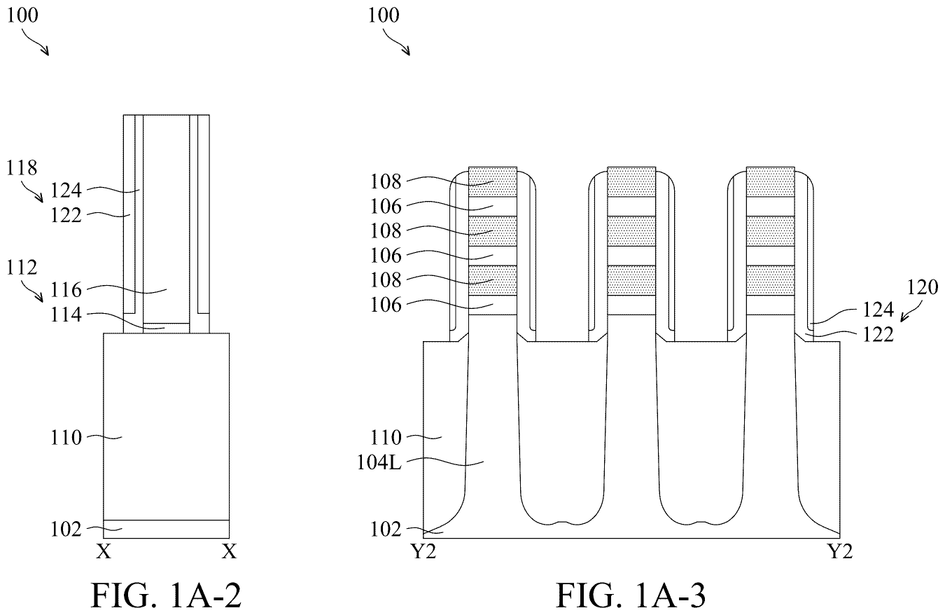

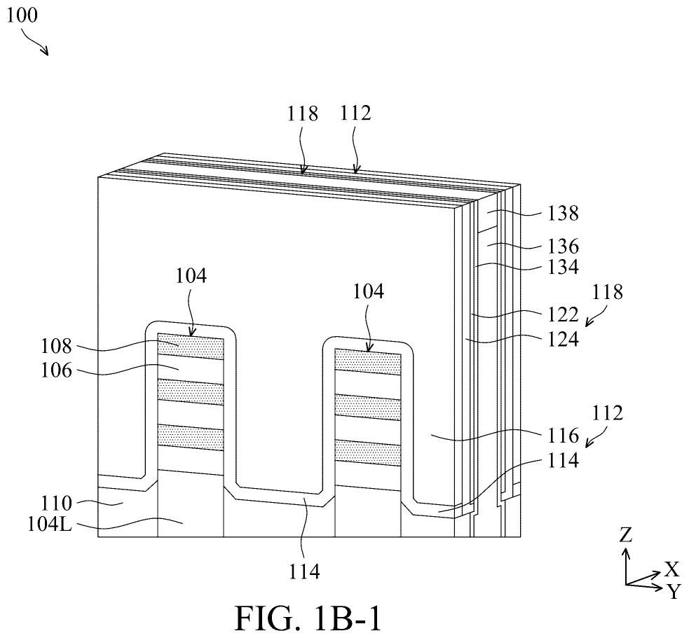

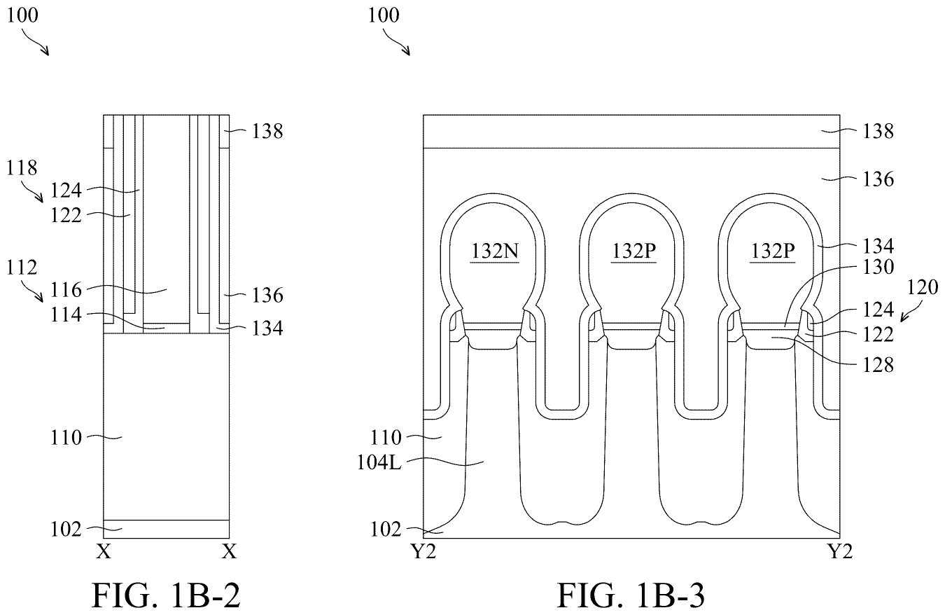

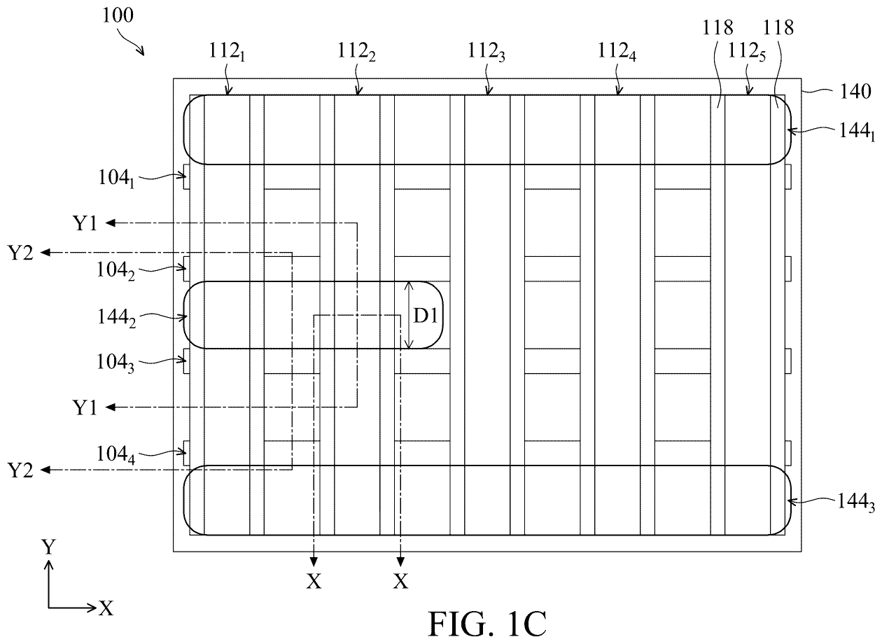

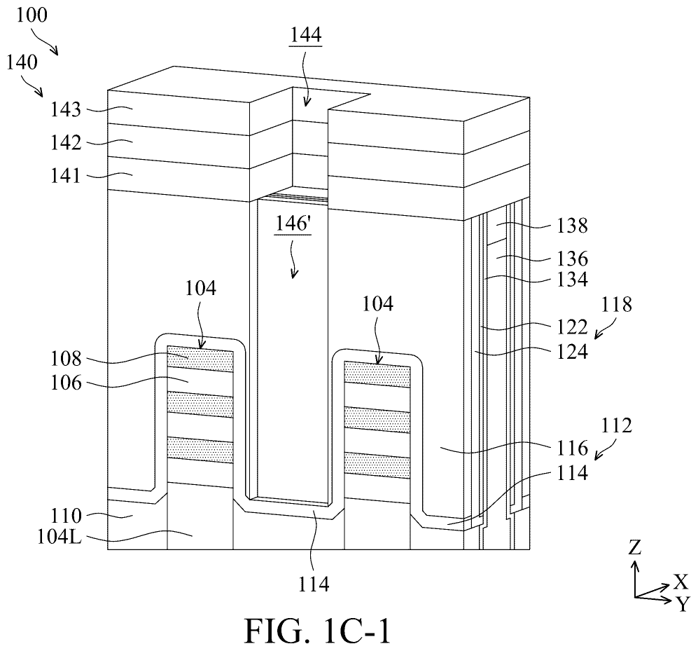

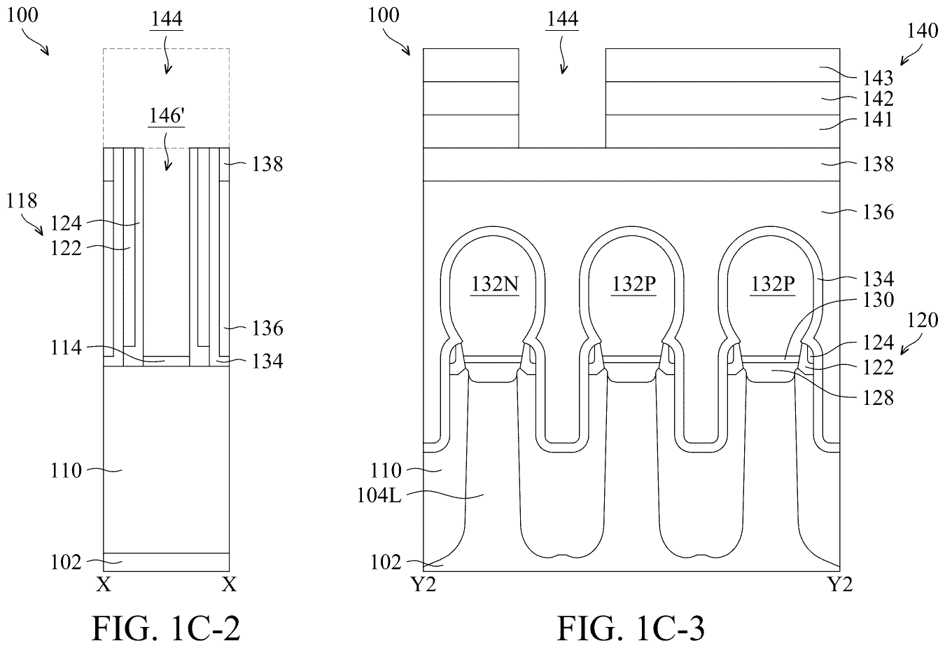

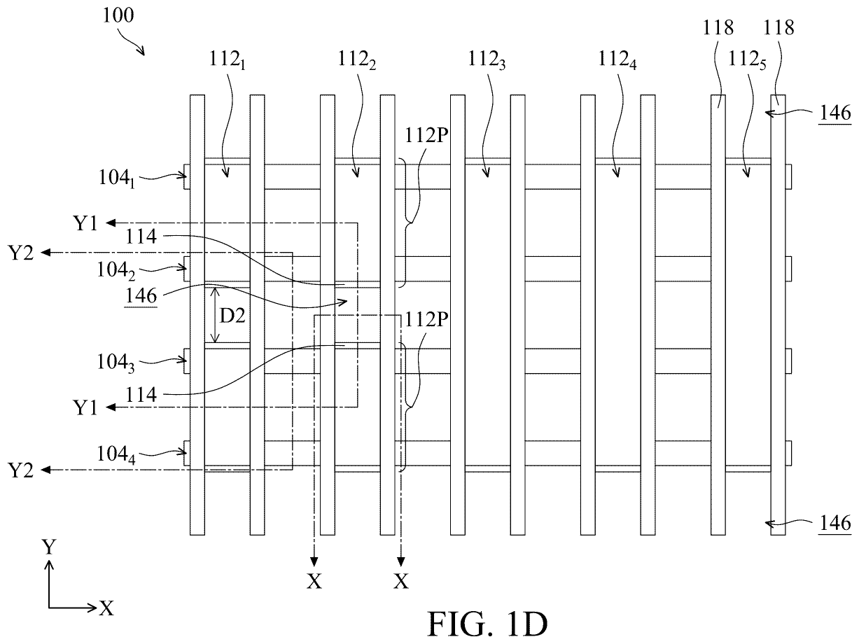

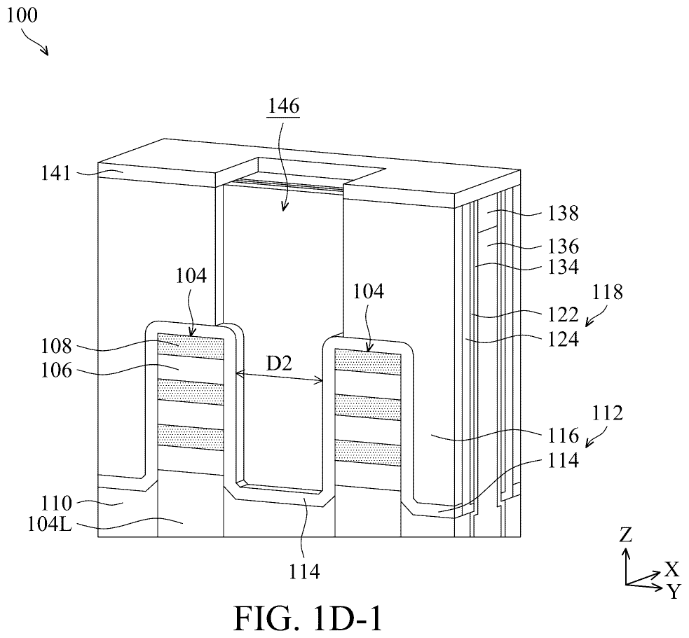

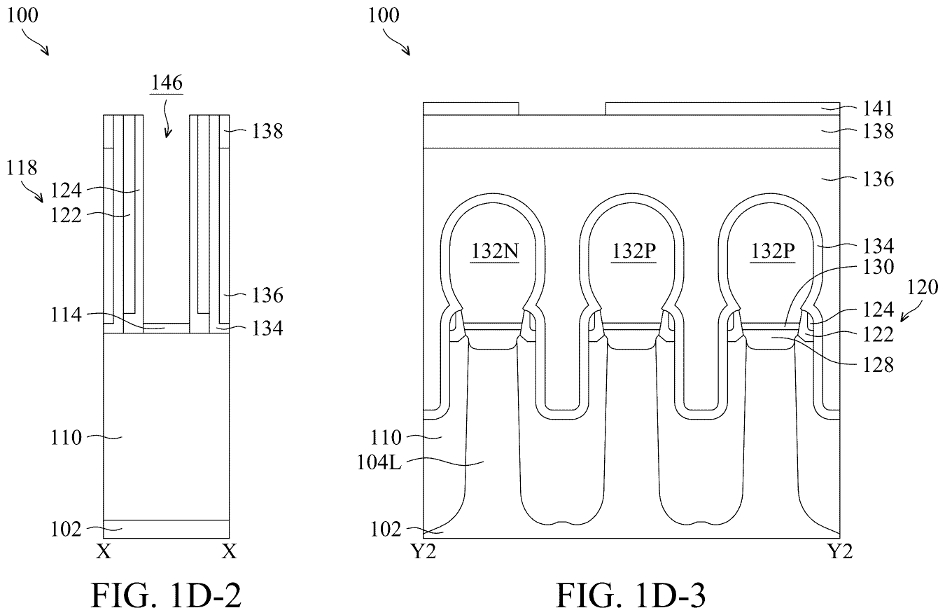

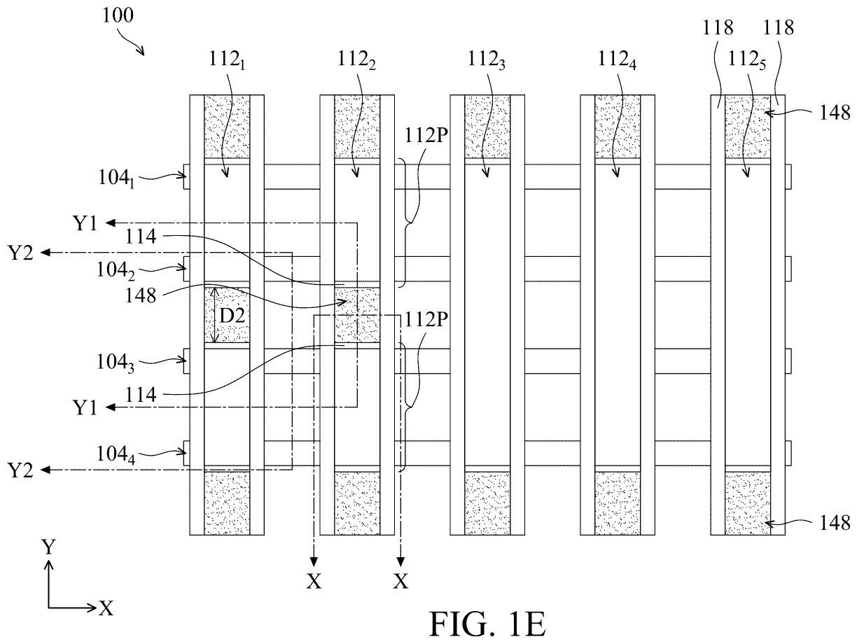

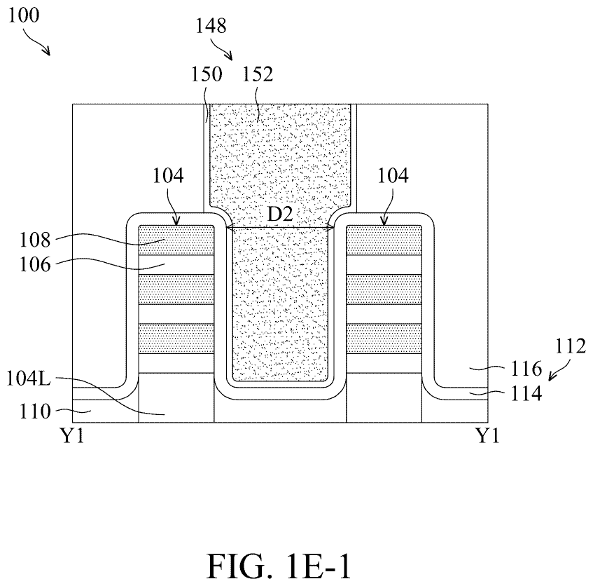

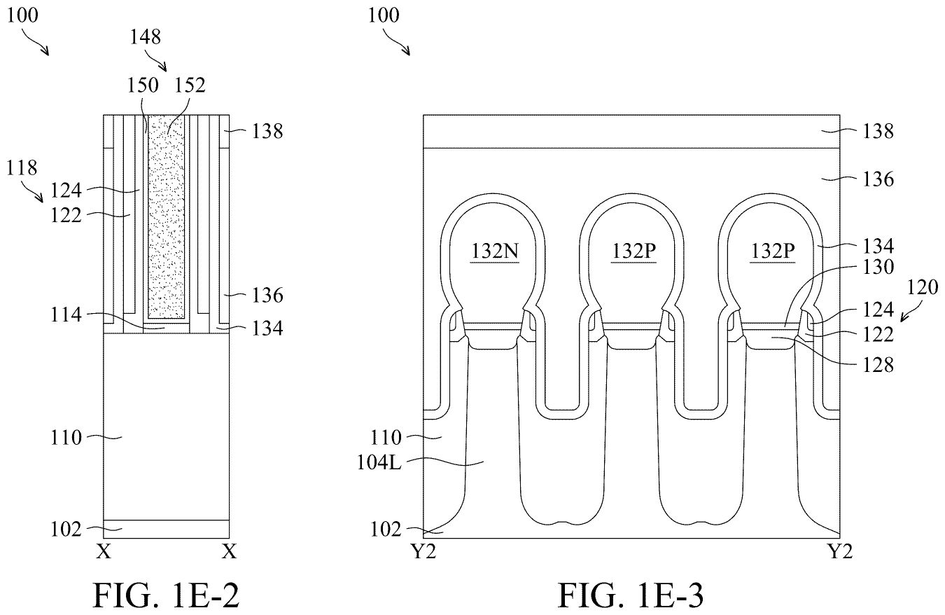

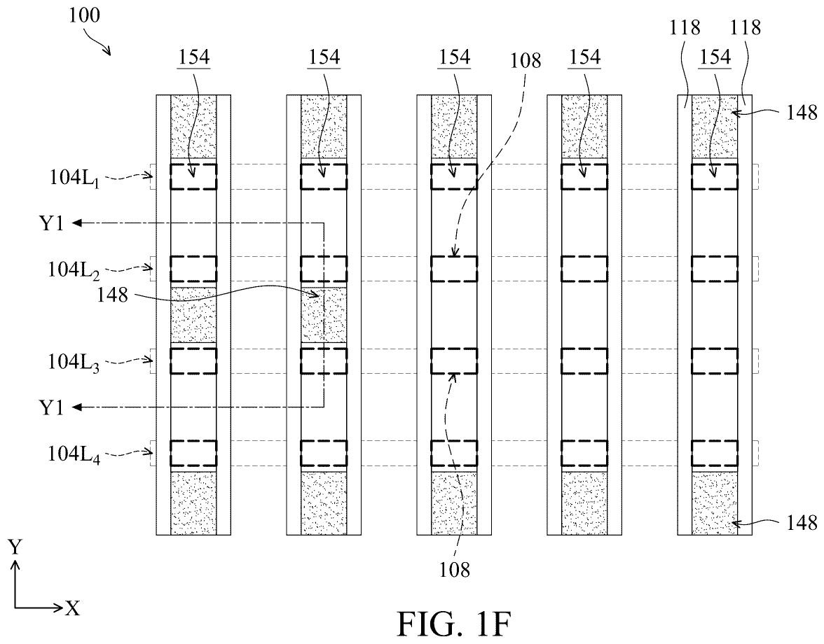

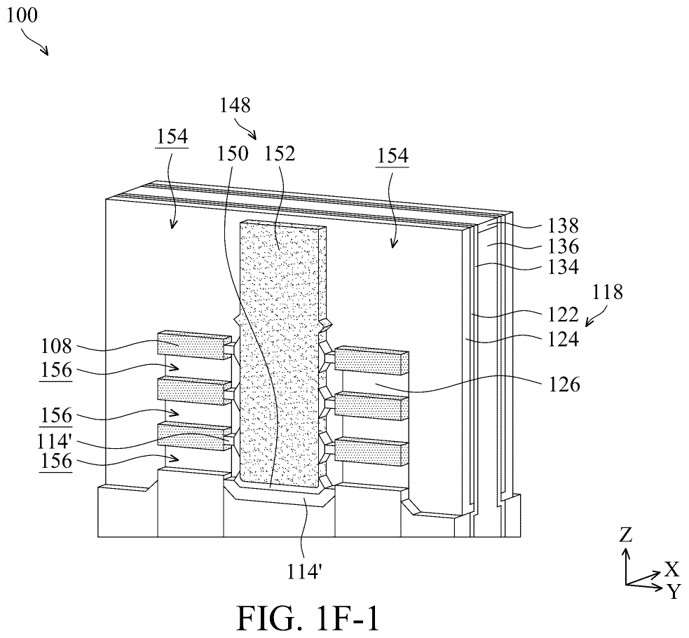

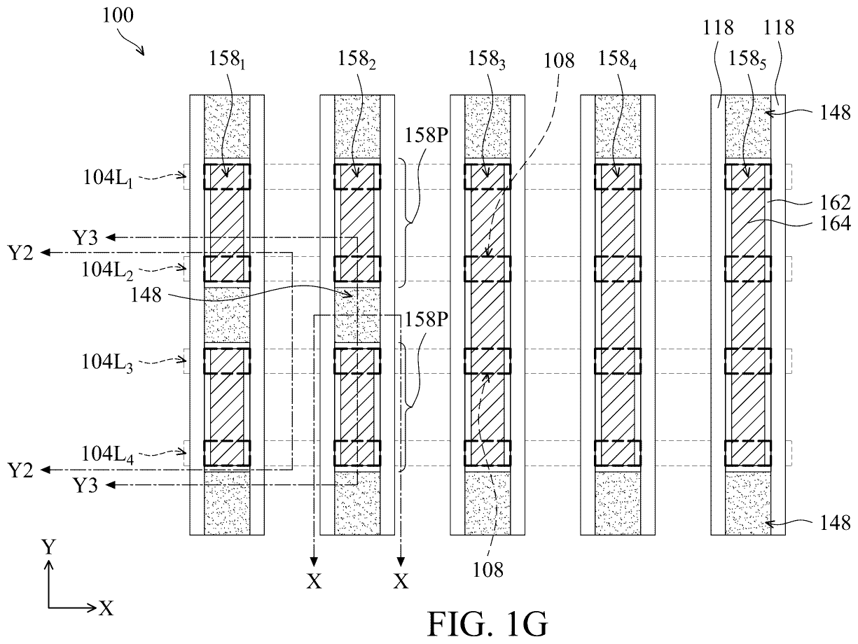

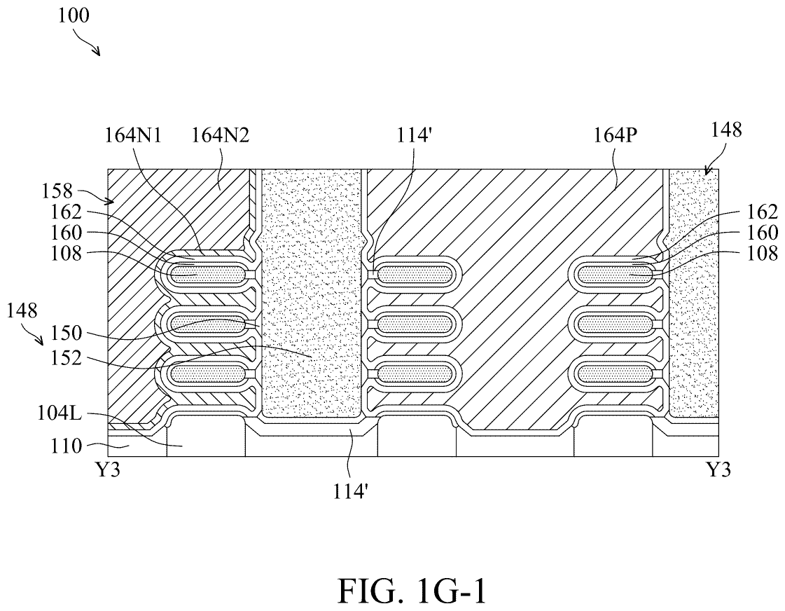

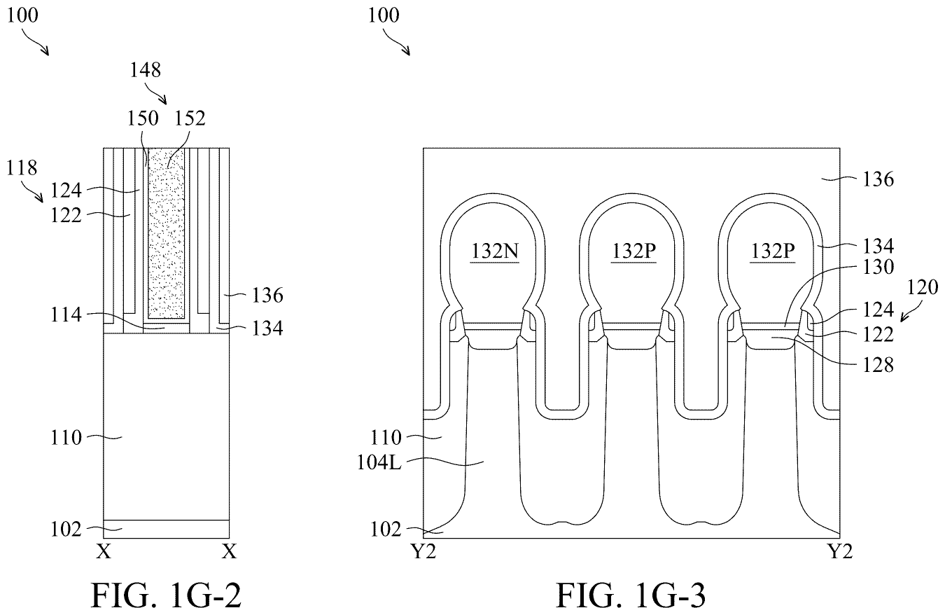

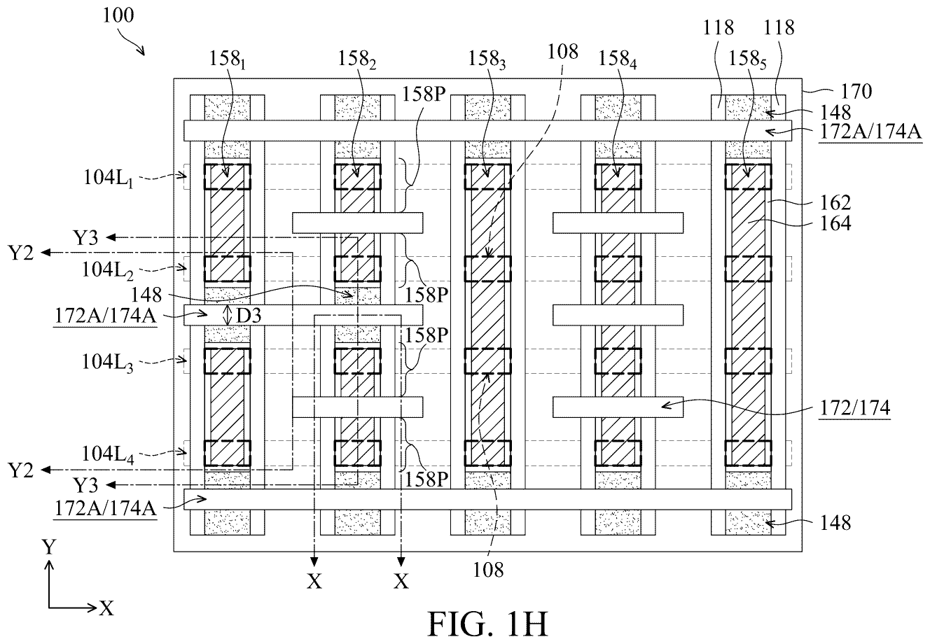

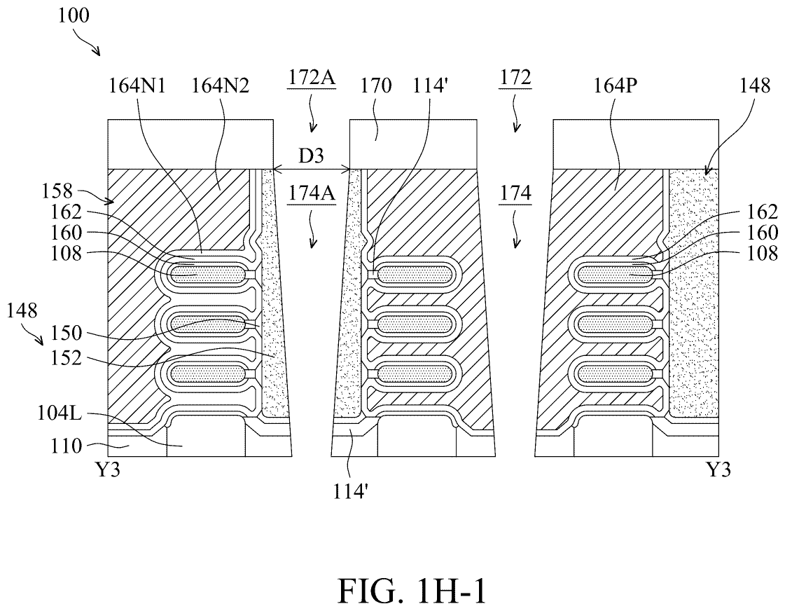

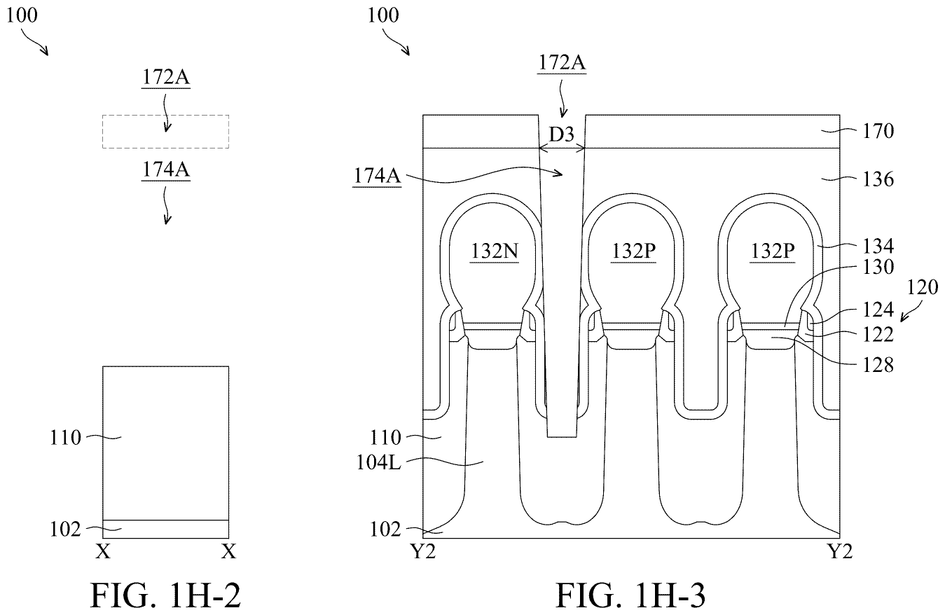

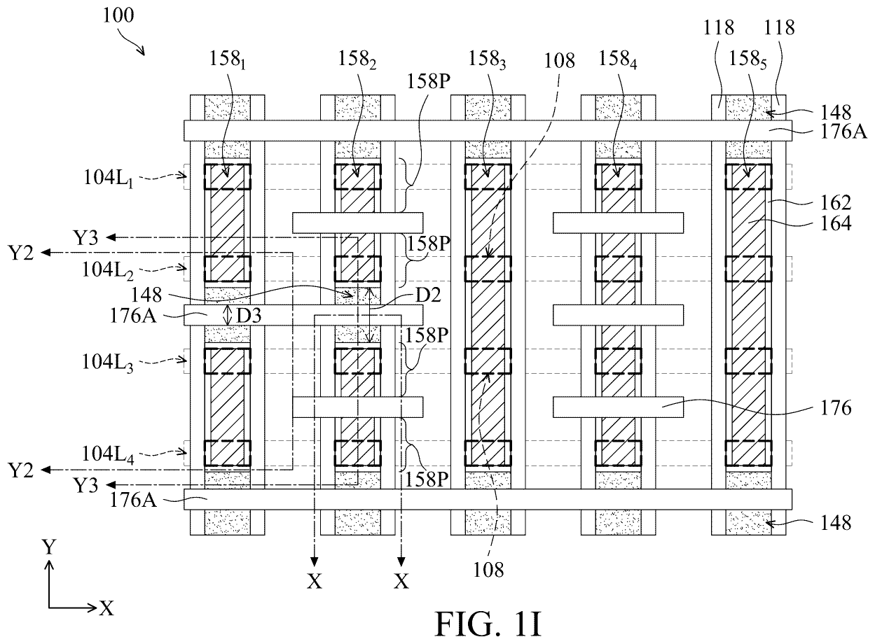

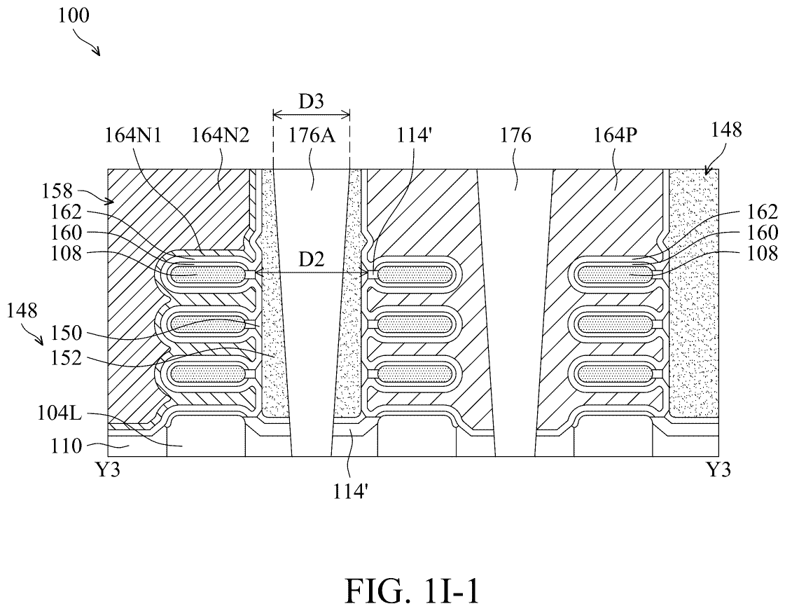

FIGS. 1A through 1I-3 are schematic views illustrating the formation of a semiconductor structure 100 at various intermediate stages, in accordance with some embodiments of the disclosure.

FIG. 1A is a top view of the semiconductor structure 100 after the formation of active regions 104, an isolation structure 110, dummy gate structures 112, gate spacer layers 118 and fin spacer layer 120. FIG. 1A-1 is a perspective view of the semiconductor structure 100 cut through line Y1-Y1 of FIG. 1A. FIGS. 1A-2 and 1A-3 are cross-sectional views of the semiconductor structure 100 corresponding to line X-X and line Y2-Y2 of FIG. 1A, respectively.

A semiconductor structure 100 is provided, as shown in FIGS. 1A, 1A-1, 1A-2 and 1A-3, in accordance with some embodiments. The semiconductor structure 100 includes a substrate 102 and active regions 104 (including 104₁ to 104₄) and an isolation structure 110 over the substrate 102, and dummy gate structures 112 (including 112₁ to 112₅) across the active regions 104 and the isolation structure 110, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

The active regions 104 extend in the X direction, in accordance with some embodiments. The active regions 104 have longitudinal axes parallel to the X direction, in accordance with some embodiments. In some embodiments, the active regions 104 are also referred to as fins or fin structures. Each of the active regions 104 is defined as several channel regions and several source/drain regions, where the channel regions and the source/drain regions are alternately arranged, in accordance with some embodiments. It is noted that in the present disclosure, source/drain region(s) may refer to a source or a drain, individually or collectively dependent upon the context. The X direction may also be referred to as the channel-extending direction. The current of the resulting semiconductor device (i.e., nanostructure transistor) flows in the X direction through the channel.

Each of the active regions 104 includes a lower fin element 104L formed from a portion of the substrate 102 and an upper fin element formed from an epitaxial stack including alternating first semiconductor layers 106 and second semiconductor layers 108, in accordance with some embodiments. The formation of the active regions 104 includes forming an epitaxial stack over the substrate 102 using an epitaxial growth process, in accordance with some embodiments. The epitaxial stack may be formed by depositing a first semiconductor layer 106 on the substrate 102, depositing a second semiconductor layer 108 on the first semiconductor layer 106, and repeating the cycle of depositing the semiconductor layers 106 and 108 several times. The first semiconductor layers 106 and the second semiconductor layers 108 are alternately stacked, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material with a different composition than the first semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, in accordance with some embodiments. The second semiconductor layers 108 will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shaped and/or sheet shape. Although three first semiconductor layers 106 and three second semiconductor layers 108 are shown, the number is not limited to three, and can be two or four, and is less than ten.

In some embodiments, the thickness of each of the first semiconductor layers 106 is in a range from about 4 nm to about 14 nm. In some embodiments, the thickness of each of the second semiconductor layers 108 is in a range from about 3 nm to about 9 nm. The thickness of the second semiconductor layers 108 may be greater than, equal to, or less than the first semiconductor layers 106, which may depend on the amount of the gate materials to be filled in spaces where the first semiconductor layers 106 are removed.

The formation of the active regions 104 further includes patterning the epitaxial stack and the underlying substrate 102 using photolithography and etching processes, thereby forming trenches and the active regions 104 protruding from between trenches, in accordance with some embodiments. The portion of the substrate 102 protruding from between the trenches serves as the lower fin elements 104L of the active regions 104, in accordance with some embodiments. The remainder of the epitaxial stack (including the first semiconductor layers 106 and the second semiconductor layers 108) serves as the upper fin elements of the active regions 104, in accordance with some embodiments.

The isolation structure 110 is formed to surround the lower fin elements 104L of the active regions 104, in accordance with some embodiments. The isolation structure 110 is configured to electrically isolate active regions 104 of the semiconductor structure 100 and is also referred to as a shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104, in accordance with some embodiments. The planarization may be chemical mechanical polishing (CMP), etching back process, or a combination thereof. The insulating material is then recessed by an etching process (such as dry plasma etching and/or wet chemical etching) to expose the sidewalls of the upper fin elements of the active regions 104, in accordance with some embodiments.

The dummy gate structures 112 are formed across the active regions 104 and the isolation structure 110, in accordance with some embodiments. The dummy gate structures 112 surround the channel regions of the active regions 104, in accordance with some embodiments. The dummy gate structures 112 are configured as sacrificial structures and will be replaced with the final gate stacks, in accordance with some embodiments. In some embodiments, the dummy gate structures 112 extend in the Y direction. The dummy gate structures 112 have longitudinal axes parallel to the Y direction, in accordance with some embodiments. The Y direction may also be referred to as a gate-routing direction.

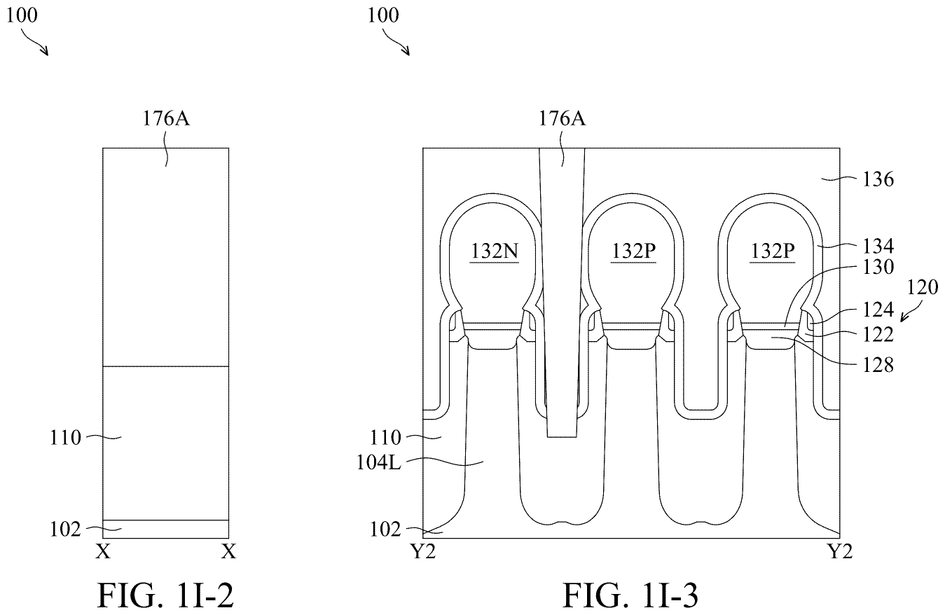

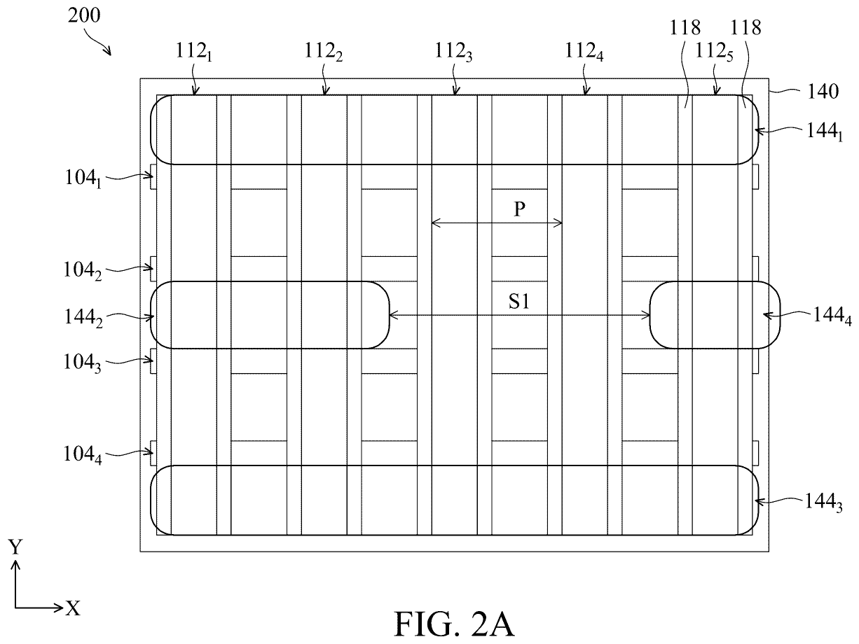

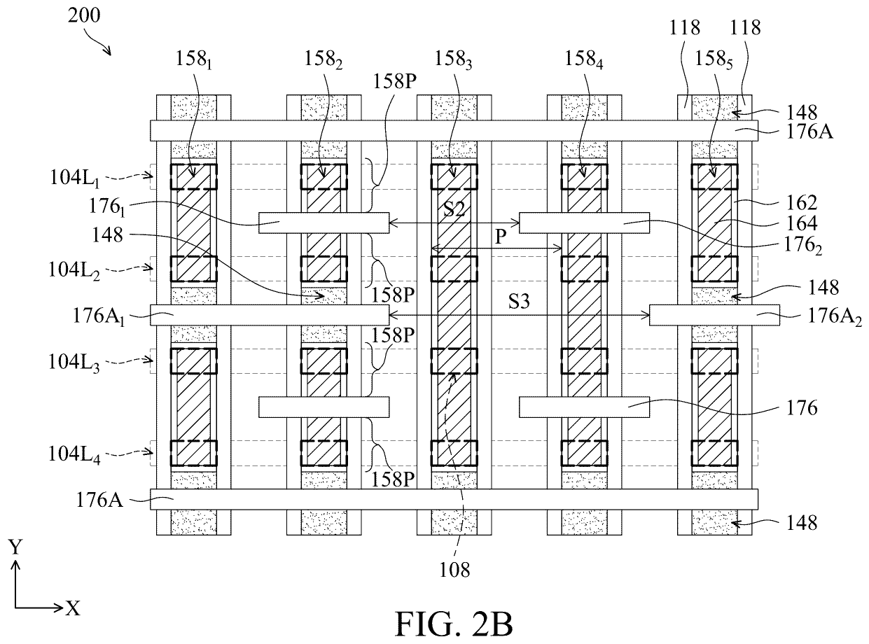

Each of the dummy gate structures 112 includes a dummy gate dielectric layer 114 and a dummy gate electrode layer 116 formed over the dummy gate dielectric layer 114, as shown in FIGS. 1A-1 and 1A-2, in accordance with some embodiments. In some embodiments, the dummy gate dielectric layer 114 extends along the upper fin elements of the active regions 104 and the isolation structure 110. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, and/or HfAlO. In some embodiments, the dummy gate electrode layer 116 is made of semiconductor materials such as polysilicon or poly-silicon germanium.

In some embodiments, the formation of the dummy gate structures 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structures 112 using photolithography and etching processes.

Gate spacer layers 118 are formed along opposite sidewalls of the dummy gate structures 112, and fin spacer layers 120 are formed along opposite sidewalls of the active regions 104, as shown in FIGS. 1A, 1A-1, 1A-2 and 1A-3, in accordance with some embodiments. The gate spacer layers 118 extend in the Y direction and across the active regions 104 and the isolation structure 110, in accordance with some embodiments. The gate spacer layers 118 are used to offset the subsequently formed source/drain features and separate the source/drain features from the gate structure, in accordance with some embodiments. The fin spacer layers 120 extend in the X direction, in accordance with some embodiments. The fin spacer layers 120 are used to confine the growth of epitaxial material to prevent neighboring epitaxial material from merging with each other, in accordance with some embodiments.

In some embodiments, the gate spacer layers 118 and the fin spacer layers 120 are formed from one or more continuous dielectric material(s). For example, in some embodiments, the formation of the gate spacer layers 118 and the fin spacer layers 120 includes globally and conformally depositing spacer layers 122 and 124 over the semiconductor structure 100 using ALD, CVD (such as LPCVD, PECVD or HDP-CVD or a combination thereof, followed by an anisotropic etching process, in accordance with some embodiments.

In some embodiments, the spacer layers 122 and 124 are made of dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the spacer layer 122 and the spacer layer 124 are made of different materials and have different dielectric constant values. For example, the spacer layers 122 and 124 are made of SiOCN with different compositions (e.g., different carbon concentrations) and different dielectric constants. In some other embodiments, the spacer layers 122 and 124 are the same material.

After the anisotropic etching process, the vertical portions of the spacer layers 122 and 124 left remaining on the opposite sides of the dummy gate structures 112 form the gate spacer layers 118, in accordance with some embodiments. The vertical portions of the spacer layers 122 and 124 left remaining on the opposite sides of the active regions 104 form the fin spacer layers 120, in accordance with some embodiments.

FIGS. 1B-1, 1B-2 and 1B-3 illustrate the semiconductor structure 100 after the formation of source/drain features 132N and 132P, a contact etching stop layer 134, an interlayer dielectric layer 136, and a dielectric cap layer 138. FIG. 1B-1 is a perspective view of the semiconductor structure 100 cut through line Y1-Y1 of FIG. 1A. FIGS. 1B-2 and 1B-3 are cross-sectional views of the semiconductor structure 100 corresponding to line X-X and line Y2-Y2 of FIG. 1A, respectively.

Source/drain features 132N and 132P are formed in and/or over the source/drain regions of the active regions 104, as shown in FIG. 1B-3, in accordance with some embodiments. The formation of the source/drain features 132N and 132P includes recessing the source/drain regions of the active regions 104 using the dummy gate structures 112 and the gate spacer layers 118 as masks to form source/drain recesses (where the source/drain features 132N and 132P are to be formed) on opposite sides of the dummy gate structures 112, in accordance with some embodiments. The source/drain recesses may extend into the lower fin elements 104L, in accordance with some embodiments. In some embodiments, the recessing process includes an anisotropic etching process such as dry plasma etching, an isotropic etching process such as dry chemical etching, remote plasma etching or wet chemical etching, or a combination thereof.

In the etching process, the isolation structure 110 is also recessed, thereby forming STI recesses, in accordance with some embodiments. In some embodiments, the bottom of the STI recess extends downward to a deeper position than the bottom of the source/drain recess. In addition, the fin spacer layers 120 are also recessed in the etching process. In some other embodiments, the isolation structure 110 is not also recessed in the etching process.

Afterward, an etching process is performed to laterally recess, from the source/drain recesses, the first semiconductor layers 106 of the active regions 104 thereby forming notches, and then inner spacer layers (not shown in FIGS. 1B-1, 1B-2 and 1B-3) are formed in the notches, in accordance with some embodiments. The inner spacer layers are formed to abut the recessed side surfaces of the first semiconductor layers 106, in accordance with some embodiments.

In some embodiments, the inner spacer layers extend directly below the gate spacer layers 118. In some embodiments, the inner spacer layers are made of dielectric material silicon oxide (SiO₂), silicon nitride (SiN), silicon carbide (SIC), silicon oxynitride (SiON), silicon carbon nitride (SiCN), silicon oxycarbonitride (SiOCN), and/or oxygen-doped silicon carbonitride (Si(O)CN.

In some embodiments, the formation of the inner spacer layers includes depositing a dielectric material for the inner spacer layers over the semiconductor structure 100 to overfill the notches, and then etching away the portion of the dielectric material outside the notches.

Semiconductor isolation features 128 are formed in the source/drain recesses on the lower fin elements 104L using an epitaxial growth process, as shown in FIG. 1B-3, in accordance with some embodiments. The epitaxial growth process may be MBE, MOCVD, or VPE, another suitable technique, or a combination thereof. In some embodiments, the semiconductor isolation features 128 are made of undoped epitaxial material such as intrinsic silicon, intrinsic silicon germanium and/or another suitable semiconductor material. In some other embodiments, the semiconductor isolation features 128 are doped with dopants having the opposite conductivity type to the source/drain features 132N and 132P. In some embodiments, the top surfaces of the semiconductor isolation features 128 are substantially flat. In some other embodiments, the top surfaces of the semiconductor isolation features 128 are curved, e.g., convex or concave.

Dielectric isolation layers 130 are formed on the semiconductor isolation features 128, in accordance with some embodiments. In some embodiments, the dielectric isolation layers 130 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric isolation layers 130 are formed by forming a deposition process, followed by an etching-back process.

The source/drain features 132N and 132P are then grown in the source/drain recesses from the exposed surfaces of the second semiconductor layers 108 using an epitaxial growth process, as shown in FIG. 1B-3, in accordance with some embodiments. The epitaxial growth process may be MBE, MOCVD, or VPE, another suitable technique, or a combination thereof. The source/drain features 132N are formed over a p-type well region and the source/drain features 132P are formed over an n-type well region, in accordance with some embodiments.

In some embodiments, the source/drain features 132N and 132P abut the inner spacer layers and the second semiconductor layers 108. In some embodiments, the source/drain features 132N and 132P are made of any suitable semiconductor material for n-type semiconductor devices or p-type semiconductor devices.

The source/drain features 132N are made of semiconductor materials such as SiP, SiAs, SiCP, SiC, Si, GaAs, another suitable semiconductor material, or a combination thereof. In some embodiments, the source/drain features 132N are doped with the n-type dopant during the epitaxial growth process. For example, the n-type dopant may be phosphorous (P) or arsenic (As). For example, the source/drain features 132N may be the epitaxially grown Si doped with phosphorous to form silicon:phosphor (Si:P) source/drain features and/or arsenic to form silicon:arsenic (Si:As) source/drain features.

The source/drain features 132P are made of semiconductor materials such as SiGe, Si, GaAs, another suitable semiconductor material, or a combination thereof. In some embodiments, the source/drain features 132P are doped with the p-type dopant during the epitaxial growth process. For example, the p-type dopant may be boron (B) or BF₂. For example, the source/drain features 132P may be the epitaxially grown SiGe doped with boron (B) to form a silicon germanium:boron (SiGe:B) source/drain feature.

The n-type source/drain features 132N and the p-type source/drain features 132P may be formed separately. The respective concentrations of the dopants in the source/drain features 132N and 132P in a range from about 1×10¹⁹ cm⁻³ to about 6×10²¹ cm⁻³. An annealing process may be performed on the semiconductor structure 100 to activate the dopants in the source/drain features 132N and 132P, in accordance with some embodiments.

A contact etching stop layer 134 is formed over the semiconductor structure 100 to cover the source/drain features 132N and 132P, as shown in FIGS. 1B-1, 1B-2 and 1B-3, in accordance with some embodiments. The contact etching stop layer 134 is further formed along, and covers, the sidewalls of the gate spacer layers 118 and the fin spacer layers 120, in accordance with some embodiments.

In some embodiments, the contact etching stop layer 134 is made of dielectric material, such as silicon nitride (SiN), silicon oxynitride (SiON), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 134 is globally and conformally deposited over the semiconductor structure 100 using CVD (such as LPCVD, PECVD, HDP-CVD, or HARP), ALD, another suitable method, or a combination thereof.

Afterward, an interlayer dielectric layer 136 is formed over the contact etching stop layer 134, as shown in FIGS. 1B-1, 1B-2 and 1B-3, in accordance with some embodiments. The interlayer dielectric layer 136 overfills the space between the dummy gate structures 112, in accordance with some embodiments. In some embodiments, the interlayer dielectric layer 136 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the interlayer dielectric layer 136 and the contact etching stop layer 134 are made of different materials and have a great difference in etching selectivity. For example, the contact etching stop layer 134 is a silicon nitride layer, and the interlayer dielectric layer 136 is a silicon oxide layer. In some embodiments, the dielectric material for the interlayer dielectric layer 136 is deposited using such as CVD (such as HDP-CVD, PECVD, HARP or FCVD), another suitable technique, or a combination thereof. The dielectric materials for the contact etching stop layer 134 and the interlayer dielectric layer 136 above the top surface of the dummy gate electrode layer 116 are removed using such as CMP, in accordance with some embodiments.

Afterward, an etching process is performed to recess the interlayer dielectric layer 136, and a dielectric cap layer 138 is formed on the interlayer dielectric layer 136, as shown in FIGS. 1B-1, 1B-2 and 1B-3, in accordance with some embodiments. In some embodiments, the dielectric cap layer 138 is made of dielectric material, such as silicon nitride (SiN), silicon oxynitride (SiON), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the dielectric cap layer 138 is formed by a deposition process such as CVD or ALD, followed by a planarization process such as an etching back process or CMP.

FIG. 1C is a top view of the semiconductor structure 100 after the formation of a patterned mask layer 140. FIG. 1C-1 is a perspective view of the semiconductor structure 100 cut through line Y1-Y1 of FIG. 1C. FIGS. 1C-2 and 1C-3 are cross-sectional views of the semiconductor structure 100 corresponding to line X-X and line Y2-Y2 of FIG. 1C, respectively.

A patterned mask layer 140 is formed over the semiconductor structure 100, as shown in FIGS. 1C, 1C-1, 1C-2 and 1C-3, in accordance with some embodiments. The patterned mask layer 140 has trench patterns 144 (including 144₁, 144₂ and 144₃), each of which is located directly above the isolation structure 110 between the active regions 104, in accordance with some embodiments. In some embodiments, the trench patterns 144 extend in the X direction and across one or more dummy gate structures 112. In some embodiments, the trench patterns 144 have a dimension D1 in the Y direction in a range from about 10 nm to about 200 nm. The trench patterns 144 may be also referred to as cut poly gate (CPO) patterns.

In some embodiments, longer trench patterns 144₁ and 144₃ extending across the dummy gate structures 112₁ to 112₅ are used to define boundaries of a cell in which a plurality of transistors will be formed and construct a functional circuit. In some embodiments, a shorter trench pattern 144₂ extending across the dummy gate structures 112₁ to 112₂ is used to cut a common gate of two transistors of the functional circuit.

The patterned mask layer 140 may be a tri-layer mask structure which includes a bottom hard mask layer 141, a middle hard mask layer 142, and a top photoresist mask 143, in accordance with some embodiments. For example, the bottom hard mask layer 141 may be bottom anti-reflective coating (BARC) layer such as an inorganic material or an organic material (e.g., polymer, oligomer, or monomer). In some embodiments, the bottom hard mask layer 141 is made of organic material including carbon and oxygen, which is made of cross-linked photo-sensitive material. In some embodiments, the fill layer 138 is formed by spin-on coating process, a CVD process (such as LPCVD, PECVD, HDP-CVD, HARP or FCVD), another suitable method, or a combination thereof.

In some embodiments, the middle hard mask layer 142 is made of silicon oxide-based material, oxide of metal such as zinc oxide (ZnO), aluminum oxide (Al₂O₃), tin oxide (SnO), lead oxide (PbO), beryllium oxide (BeO), chromium oxide (CrO, Cr₂O₃, Cr₂O₃ or Cr₃O₄), and/or another suitable material.

The top photoresist mask 143 is formed by a photolithography process, in accordance with some embodiments. The photolithography process can include forming a photoresist layer, for example, by spin coating, performing a pre-exposure baking process, performing an exposure process using a mask (or a reticle), performing a post-exposure baking process, and performing a developing process. During the exposure process, the photoresist layer is exposed to radiation energy, where the mask blocks, transmits, and/or reflects radiation to the photoresist layer depending on a mask pattern of the mask and/or mask type, such that an image is projected onto the photoresist layer that corresponds with the mask pattern. In some embodiments, the photoresist layer is patterned with immersion lithography using ultraviolet light at a wavelength of 193 nm, and the trench patterns 144 may have round corners, as shown in FIG. 1C. Since the photoresist layer is sensitive to radiation energy, exposed portions of the resist layer chemically change, and exposed (or non-exposed) portions of the resist layer are dissolved during the developing process depending on the characteristics of the resist layer and characteristics of a developing solution used in the developing process. After development, the patterned photoresist layer forms the top photoresist mask 143 which includes the trench patterns 144 that correspond with the mask.

An etching process is performed on the semiconductor structure 100 using the patterned mask layer 140, in accordance with some embodiments. The etching process may be anisotropic etching process such as dry plasma etching. The etching process removes the bottom hard mask layer 141 and the middle hard mask layer 142 exposed from the trench patterns 144, thereby transferring the trench patterns 144 into the middle hard mask layer 142 and the bottom hard mask layer 141, as shown in FIGS. 1C-1, 1C-2 and 1C-3, in accordance with some embodiments. The etching process further removes the dummy gate electrode layers 116 exposed from the trench patterns 144, thereby forming openings 146′, in accordance with some embodiments.

In the etching process, the portions of the gate spacer layers 118, the contact etching stop layer 134 and the dielectric cap layer 138 exposed from the trench patterns 144 are substantially unetched or only slightly etched due to the difference in the etching selectivity between the dummy gate electrode layers 116 and these dielectric layers, as shown in FIGS. 1C-1, 1C-2 and 1C-3, in accordance with some embodiments. Therefore, the openings 146′ do not extend between the source/drain features 132N/132P.

In some embodiments, the dimension D1 of the trench patterns 144 may be less than the spacing between the active regions 104, and thus the opposite sidewalls of the openings 146′ extending in the X direction are defined by the portions of the dummy gate electrode layers 116 proximate to the sidewalls of the active regions 104, as shown in FIG. 1C-1, in accordance with some embodiments. The opposite sidewalls of the openings 146′ extending in the Y direction are defined by the gate spacer layers 118, as shown in FIGS. 1C-1 and 1C-2, in accordance with some embodiments. If the dimension D1 of the trench patterns 144 is greater than the spacing between the active regions 104, the risk of damage to the active regions 104 caused by the etching process may increase.

The etching process may be performed until a portion of the dummy gate dielectric layer 114 along the upper surface of the isolation structure 110 is exposed from the opening 146′, as shown in FIGS. 1C-1 and 1C-2, in accordance with some embodiments. The patterned mask layer 140 may be removed in the etching process and/or by an additional removal process (e.g., ashing, etching or wet strip process).

FIG. 1D is a top view of the semiconductor structure 100 after a trimming process. FIG. 1D-1 is a perspective view of the semiconductor structure 100 cut through line Y1-Y1 of FIG. 1D. FIGS. 1D-2 and 1D-3 are cross-sectional views of the semiconductor structure 100 corresponding to line X-X and line Y2-Y2 of FIG. 1D, respectively.

A trimming process is performed to laterally recess, from the opening 146′, the dummy gate electrode layer 116, thereby laterally enlarging the openings 146′, as shown in FIGS. 1D and 1D-1. The enlarged opening 146′ are referred to as gate-cut openings 146. The trimming process may be an isotropic etching process such as dry chemical etching, remote plasma etching or wet chemical etching, and/or a combination thereof. In the trimming process, the portions of the dummy gate electrode layers 116 proximate to the sidewalls of the active regions 104 are removed until a portion of the dummy gate dielectric layer 114 along the sidewalls of the isolation structure 110 is exposed from the gate-cut openings 146, as shown in FIGS. 1D and 1D-1, in accordance with some embodiments.

In some embodiments, the trimming process may include an over-etching step to completely remove the dummy gate electrode layers 116 along the sidewalls of the active regions 104. Thus, an upper portion of the gate-cut openings 146 above the active regions 104 may be wider in the Y direction than the lower portion of the gate-cut openings 146 between the active regions 104, as shown in FIG. 1D-1, in accordance with some embodiments. In some other embodiments, the upper portion of the gate-cut openings 146 and the lower portion of the gate-cut openings 146 have the same dimension in the Y direction. In some embodiments, the dimension D2 of the gate-cut openings 146 between the active regions 104 in the Y direction in a range from about 10 nm to about 200 nm.

The dummy gate structures 112 are cut through by the gate-cut openings 146 into several dummy gate segments 112P, as shown in FIG. 1D, in accordance with some embodiments. The opposite sidewalls of the gate-cut openings 146 extending in the X direction are defined by the dummy gate dielectric layer 114, and the opposite sidewalls of the gate-cut openings 146 extending in the Y direction are defined by the gate spacer layers 118, in accordance with some embodiments.

FIG. 1E is a top view of the semiconductor structure 100 after the formation of wall structures 148. FIGS. 1E-1, 1E-2 and 1E-3 are cross-sectional views of the semiconductor structure 100 corresponding to line Y1-Y1, line X-X and line Y2-Y2 of FIG. 1D, respectively.

Wall structures 148 are formed in the gate-cut openings 146, as shown in FIGS. 1E, 1E-1 and 1E-2, in accordance with some embodiments. In some embodiments, along one dummy gate structure 112, the wall structure 148 is disposed on only one side of the active region 104. Otherwise, it may be hard to remove the first semiconductor layers 106 of the active region 104 in the channel region in the following channel-release process.

The space (here is the thickness of the dummy gate dielectric layer 114) between an active region 104 and a gate-cut feature (e.g., the wall structures 148) may be referred to as an end-cap dimension. The wall structures 148 (or the gate-cut openings 146) are configured to cut the gate in a manner that minimizes the end-cap dimension, and thus the overlapping area between the source/drain features and the subsequently formed final gate stack may be reduced. As a result, the total cell parasitic capacitance of the resulting semiconductor device may be reduced, and the performance (e.g., speed) of the resulting semiconductor device may be enhanced.

The formation of the wall structures 148 includes conformally depositing a dielectric lining layer 150 along the semiconductor structure 100 to partially fill the gate-cut openings 146, depositing a dielectric bulk layer 152 over the dielectric lining layer 150 to overfill the gate-cut openings 146, and planarizing the dielectric lining layer 150 and the dielectric bulk layer 152, in accordance with some embodiments.

The dielectric lining layer 150 and the dielectric bulk layer 152 are made of dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the dielectric lining layer 150 and the dielectric bulk layer 152 are made of different materials and have different dielectric constant values. For example, the dielectric lining layer 150 and the dielectric bulk layer 152 are made of SiOCN with different compositions (e.g., different carbon concentrations). In some embodiments, the dielectric lining layer 150 has a higher dielectric constant than the dielectric bulk layer 152.

The deposition processes may be ALD, CVD (such as LPCVD, PECVD or HDP-CVD or a combination thereof, in accordance with some embodiments. The planarization process may be CMP or an etching-back process, in accordance with some embodiments. The planarization process is performed until the upper surface of the gate electrode layer 116 is exposed, in accordance with some embodiments. In some embodiments, the dimension D2 of the wall structures 148 between the active regions 104 in the Y direction in a range from about 10 nm to about 200 nm.

FIG. 1F is a top view of the semiconductor structure 100 after the formation of gate trenches 154 and gaps 156. FIG. 1F-1 is a perspective view of the semiconductor structure 100 cut through line Y1-Y1 of FIG. 1F.

The dummy gate structures 112 are removed using an etching process to form gate trenches 154 between the gate spacer layers 118, as shown in FIGS. 1F, 1F-1 and 1F-2, in accordance with some embodiments. In some embodiments, the gate trenches 154 expose the channel regions of the active regions 104. In some embodiments, the gate trenches 154 further expose the sidewalls of the gate spacer layers 118 facing the channel region. Afterward, an etching process is performed on the first semiconductor layers 106 of the active regions 104 to form gaps 156, as shown in FIGS. 1F-1, in accordance with some embodiments. The etching processes include an anisotropic etching process such as dry plasma etching, an isotropic etching process such as dry chemical etching, remote plasma etching or wet chemical etching, or a combination thereof.

FIG. 1F-1 also illustrates inner spacer layers 126 which may be used as an etching stop layer in the etching process for removing the first semiconductor layers 106. The inner spacer layers 126 may protect the source/drain features 132N and 132P from being damaged, in accordance with some embodiments.

In some embodiments, the gaps 156 also expose the sidewalls of the inner spacer layers 124 facing the channel regions. The dummy gate dielectric layer 114 is also etched in the etching processes, and remainders 114′ of the dummy gate dielectric layer 114 leave under the wall structures 110 and between the wall structures 110 and the second semiconductor layers 108, as shown in FIGS. 1F and 1F-1. In addition, the dielectric lining layer 150 of the wall structures 110 are also partially removed in the etching processes. For example, the dielectric lining layer 150 above the active regions 104 are completely removed, as shown in FIG. 1F-1.

After the etching processes, the four main surfaces of the second semiconductor layers 108 are exposed, in accordance with some embodiments. The exposed second semiconductor layers 108 form nanostructures 108, in accordance with some embodiments. The nanostructures 108 are stacked vertically over the lower fin elements 104 (including 104L₁ to 104L₄), and spaced apart from one other, in accordance with some embodiments. The nanostructures 108 function as channel layers of the resulting semiconductor devices (e.g., nanostructure transistors such as GAA transistors), in accordance with some embodiments. In some embodiments, a trimming process may be performed on the nanostructures 108 to shape the profiles of the nanostructures 108, e.g., rounding the corners of the nanostructures 108.

FIG. 1G is a top view of the semiconductor structure 100 after the formation of final gate stacks 158. FIGS. 1G-1, 1G-2 and 1G-3 are cross-sectional views of the semiconductor structure 100 corresponding to line Y3-Y3, line X-X and line Y2-Y2 of FIG. 1G, respectively.

Final gate stacks 158 (including 1581 to 1585) are formed in the gate trenches 154 and gaps 156, thereby wrapping around the nanostructures 108, as shown in FIGS. 1G and 1G-1, in accordance with some embodiments. In some embodiments, the final gate stacks 158 extend in the Y direction. The final gate stacks 158 have longitudinal axes parallel to the Y direction, in accordance with some embodiments. The final gate stacks 158 include several gate segments 158P which are physically and electrically isolated from each other by the wall structures 148, in accordance with some embodiments. In some embodiments, each of the final gate stacks 158 includes an interfacial layer 160, a gate dielectric layer 162 and a metal gate electrode layer 164, as shown in FIGS. 1F and 1F-2, in accordance with some embodiments.

The interfacial layer 160 is formed on the exposed surfaces of the nanostructures 108 and the exposed top surfaces of the lower fin elements 104L, in accordance with some embodiments. The interfacial layer 160 wraps around the nanostructures 108, in accordance with some embodiments. In some embodiments, the interfacial layer 160 is made of a chemically formed silicon oxide. In some embodiments, the interfacial layer 160 is nitrogen-doped silicon oxide. In some embodiments, the interfacial layer 160 is formed using one or more cleaning processes such as including ozone (03), ammonia hydroxide-hydrogen peroxide-water mixture, and/or hydrochloric acid-hydrogen peroxide-water mixture. Semiconductor material from the nanostructures 108 and the lower fin elements 104L is oxidized to form the interfacial layer 160, in accordance with some embodiments.

The gate dielectric layer 162 is formed conformally along the interfacial layer 160 to wrap around the nanostructures 108, in accordance with some embodiments. The gate dielectric layer 162 is also conformally formed along the sidewalls of the gate spacer layers 118 facing the channel region, in accordance with some embodiments. The gate dielectric layer 162 is also conformally formed along the sidewalls of the inner spacer layers 124 facing the channel region, in accordance with some embodiments. In addition, the gate dielectric layer 162 is also conformally formed along the sidewalls of the wall structures 148, and in direct contact with dielectric lining layer 150 and the dielectric bulk layer 152, in accordance with some embodiments.

The gate dielectric layer 162 may be a high-k dielectric layer. In some embodiments, the high-k dielectric layer is dielectric material with a high dielectric constant (k value), for example, greater than 10, such as greater than 20, such as greater than 30. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), a combination thereof, or another suitable material. The high-k dielectric layer may be deposited using ALD, PVD, CVD, and/or another suitable technique.

The metal gate electrode layer 164 is formed to overfill remainders of the gate trenches 154 and gaps 156, in accordance with some embodiments. In some embodiments, the metal gate electrode layer 164 is made of more than one conductive material, such as a metal, metal alloy, conductive metal oxide and/or metal nitride, another suitable conductive material, and/or a combination thereof. For example, the metal gate electrode layer 164 includes n-type work function metal materials 164N1 and 164N2 formed over a p-type well region and a p-type work function metal material 164P formed over an n-type well region, in accordance with some embodiments. In some embodiments, the work function metal materials 164N1, 164N2 and 164P have selected work functions to enhance the device performance (e.g., threshold voltage) for n-channel FETs or p-channel FETs. The n-type work function metal materials 164N1 and 164N2 and the p-type work function metal material 164P may be formed separately.

In some embodiments, the work function metal materials 164N1, 164N2 and 164P are made of more than one conductive material, such as TiN, TaN, TiAl, TiAIN, TaAl, TaAIN, TaAIC, TaCN, WNC, Co, Pt, W, Ti, Ag, Al, TaC, TaSiN, Mn, Zr, Ru, Mo, WN, Cu, W, Re, Ir, Ni, another suitable conductive material, or multilayers thereof. The work function metal materials 164N1, 164N2 and 164P may be formed using ALD, PVD, CVD, e-beam evaporation, or another suitable technique.

A planarization process such as CMP may be performed on the semiconductor structure 100 to remove the materials of the gate dielectric layer 162 and the metal gate electrode layer 164 formed above the top surface of the interlayer dielectric layer 136, in accordance with some embodiments. In some embodiments, the dielectric cap layer 138 is also removed.

The final gate stacks 158 engage the channel regions so that current can flow between the source/drain features 132N/132P during operation. The final gate stacks 158 that are wrapped around the nanostructures 108 combine with the neighboring source/drain features 132N/132P to form nanostructure transistors, e.g., n-channel nanostructure transistors and/or p-channel nanostructure transistors.

FIG. 1H is a top view of the semiconductor structure 100 after the formation of a patterned mask layer 170. FIGS. 1H-1, 1H-2 and 1H-3 are cross-sectional views of the semiconductor structure 100 corresponding to line Y3-Y3, line X-X and line Y2-Y2 of FIG. 1H, respectively.

A patterned mask layer 170 is formed over the semiconductor structure 100, as shown in FIGS. 1H, 1H-1, 1H-2 and 1H-3, in accordance with some embodiments. The patterned mask layer 170 has trench patterns 172 (including 172A), each of which is located directly above the isolation structure 110 between the lower fin elements 104L, in accordance with some embodiments. Some 172A of the trench patterns 172 correspond to the wall structures 148, in accordance with some embodiments. In specific, each of the trench patterns 172A is disposed at the position of the corresponding trench pattern 144 in FIG. 1C, in accordance with some embodiments.

In some embodiments, the trench patterns 172 extend in the X direction and across one or more dummy gate structures 112. In some embodiments, the trench patterns 172 have a dimension D3 in the Y direction in a range from about 5 nm to about 100 nm.

In some embodiments, the dimension D3 of the trench patterns 172 is less than the dimension D2 of the trench patterns 144. The trench patterns 172 may be also referred to as cut metal gate (CMG) patterns. In some embodiments, the trench patterns 172 are used to cut a common gate of two transistors of a functional circuit.

The patterned mask layer 170 may be a patterned hard mask layer, a patterned photoresist layer, and/or a combination thereof. For example, a hard mask layer may include, or be formed of, a nitrogen-free anti-reflection layer (NFARL), carbon-doped silicon dioxide (e.g., SiO₂:C), titanium nitride (TiN), titanium oxide (TiO), boron nitride (BN), a multilayer thereof, or another suitable material. A photoresist layer is formed over the hard mask layer, and patterned with trench patterns 172 using a photolithography process that may be similar to the photolithography process described above. In some embodiments, the photolithography process uses EUV (extreme ultraviolet), and the trench patterns 172 may have sharp corners, as shown in FIG. 1H.

An etching process is performed to transfer the trench patterns 172 into the hard mask layer, in accordance with some embodiments. The etching process may be anisotropic etching process such as dry plasma etching. The etching process further removes portions of the final gate stacks 158, the interlayer dielectric layer 136, the contact etching stop layer 134, the gate spacer layers 118 and the wall structures 148 exposed from the trench patterns 172, thereby forming gate-cut openings 174 (including 174A), as shown in FIGS. 1H, 1H-1, 1H-2 and 1H-3, in accordance with some embodiments. The gate-cut openings 174 further extend into the isolation structure 110, in accordance with some embodiments.

The final gate stacks 158 are cut through into more gate segments 158P by the gate-cut openings 174 which are physically and electrically isolated from each other, as shown in FIG. 1H, in accordance with some embodiments. The gate-cut openings 174A cut through the wall structures 148, in accordance with some embodiments. The gate-cut openings 174 extend between the source/drain features 132N/132P, in accordance with some embodiments. The patterned mask layer 170 may be removed in the etching process and/or by an additional removal process (e.g., ashing, etching or wet strip process).

FIG. 1I is a top view of the semiconductor structure 100 after the formation of gate-cut structures 176. FIGS. 1I-1, 1I-2 and 1I-3 are cross-sectional views of the semiconductor structure 100 corresponding to line Y3-Y3, line X-X and line Y2-Y2 of FIG. 1I, respectively.

Gate-cut structures 176 (including 176A) are formed in the gate-cut openings 174 (including 174A), as shown in FIGS. 1I, 1I-1, 1I-2 and 1I-3, in accordance with some embodiments. The gate-cut structures 176A correspond to the wall structures 148 and include portions surrounded by the wall structures 148, in accordance with some embodiments. In some embodiments, the gate-cut structures 176A extend in the X direction. In some embodiments, the gate-cut structures 176 have a dimension D3 in the Y direction in a range from about 5 nm to about 100 nm. In some embodiments, the dimension D3 of the gate-cut structures 176 is less than the dimension D2 of the wall structures 148.

The formation of the gate-cut structures 176 includes depositing dielectric material over the semiconductor structure 100 to overfill the gate-cut openings 174, and planarizing the dielectric material, in accordance with some embodiments. The dielectric material may be silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), another suitable dielectric material, or a combination thereof. The planarization process may be CMP or an etching-back process, in accordance with some embodiments. The planarization process is performed until the upper surface of the metal gate electrode layer 164 is exposed, in accordance with some embodiments.

Compared to the formation of the gate-cut structures 176 (CMG patterns), the formation of the wall structures 148 (CPO patterns) may achieve smaller end-cap dimensions, and avoid variations in the transistor threshold voltages caused by the cutting process of the final gate stacks 158. In accordance with the embodiments of the present disclosure, the trench patterns 144 (CPO patterns) are formed using an immersion lithography with a wavelength of 193 nm (hereinafter referred to as 193 nm immersion), and the trench patterns (CMG patterns) 172 are formed using EUV lithography. The 193 nm immersion has a better cost advantage than EUV lithography, but it is subject to greater process limitations.

For example, an end-to-end spacing between neighboring two trench patterns 144 in the same row (X direction) is greater than the end-to-end spacing between neighboring two trench patterns 172 in the same row (X direction). In addition, when the end-to-end spacing is too short, some of the trench patterns 144 may experience a more corner rounding effect than the trench patterns 172 due to the characteristics of 193 nm immersion, causing the pattern to retreat. In this case, the dummy gate electrode layer 116 may be not completely cut off by the opening 146, which may allow the dummy gate segments 112P to be connected to each other with the remaining gate electrode layer. As a result, the gate segments 158P may be connected.

In accordance with the embodiments of the present disclosure, the gate-cut structures 176A are formed through the wall structures 148, which may ensure that the final gate stack 172 will be completely cut off by the gate-cut opening 174A (or the gate-cut structure 176A) if the dummy gate electrode layer 116 is not completely cut off by the opening 146 (or the wall structures 148). Therefore, the embodiments combine CPO patterns (formed by 193 nm immersion) and CMG patterns (formed by EUV lithography) as the gat-cut features to achieve a good balance between manufacturing cost and performance and reliability of the resulting semiconductor device.

It should be understood that the semiconductor structure 100 may undergo further CMOS processes to form various features over the semiconductor structure, such as a multilayer interconnect structure (e.g., contact plugs, conductive vias, metal lines, inter metal dielectric layers, passivation layers, etc.).

FIGS. 2A and 2B are top views illustrating the formation of a semiconductor structure 200 at various intermediate stages, in accordance with some embodiments of the disclosure. The embodiments of FIGS. 2A and 2B are similar to the embodiments of FIGS. 1A to 1I-3 except two neighboring trench patterns 144 are formed in the same row (X direction).

Continuing from FIG. 1B, a patterned mask layer 140 is formed over the semiconductor structure 200, as shown in FIG. 2A, in accordance with some embodiments. The trench patterns 144₂ and 144₄ are located between the active regions 1042 and 1043, in accordance with some embodiments. In some embodiments, the distance S1 (i.e., end-to-end spacing) between the trench patterns 144₂ and 144₄ is greater than 1.5 times the pitch P of the dummy gate structures 112, and may be smaller than 2 times the pitch P. In some embodiments, the distance S1 may be the minimum end-to-end spacing of the trench patterns 144 achieved using the 193 nm immersion.

The steps described above in FIGS. 1C to 1I-3 are performed, thereby forming wall structures 148, final gate stacks 158 and gate-cut structures 176, as shown in FIG. 2B, in accordance with some embodiments.

In some embodiments, the distance S2 (i.e., end-to-end spacing) between the gate-cut structures 1761 and 1762 may be the minimum end-to-end spacing of the trench patterns 172 achieved using the EUV lithography, as shown in FIG. 2B. The distance S2 is less than the pitch P of the dummy gate structures 112. In some embodiments, the gate-cut structures 176A1 and 176A2 are disposed at the position of the corresponding trench patterns 144₂ and 144₄ (FIG. 2A), and the distance S3 between the gate-cut structures 176A1 and 176A2 is substantially equal to the distance S1 (FIG. 2A), and greater than the distance S2.

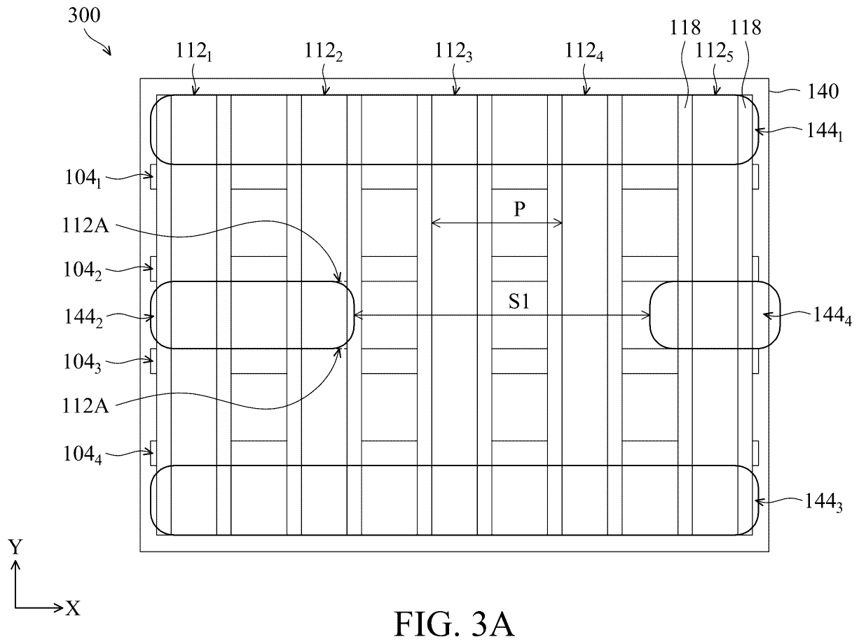

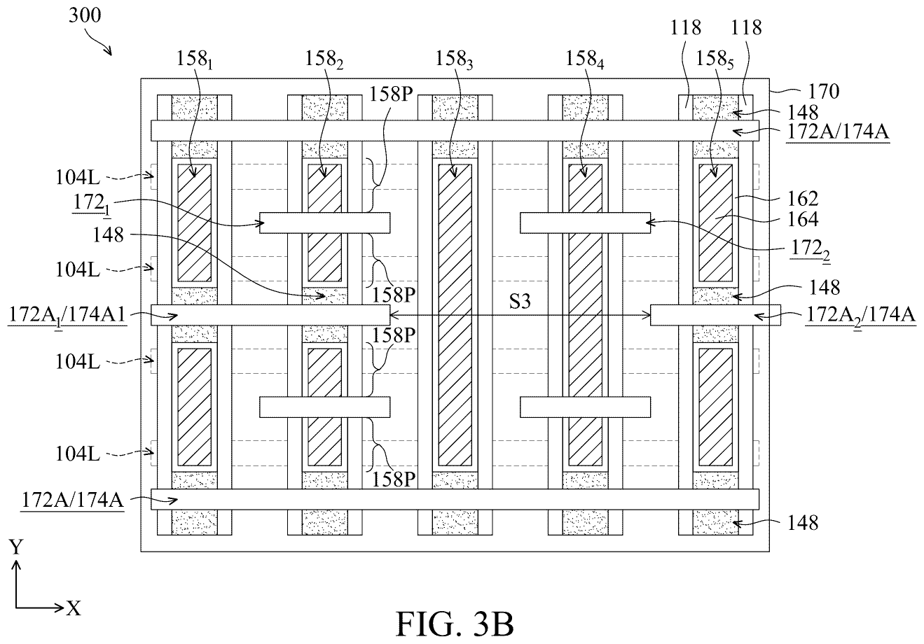

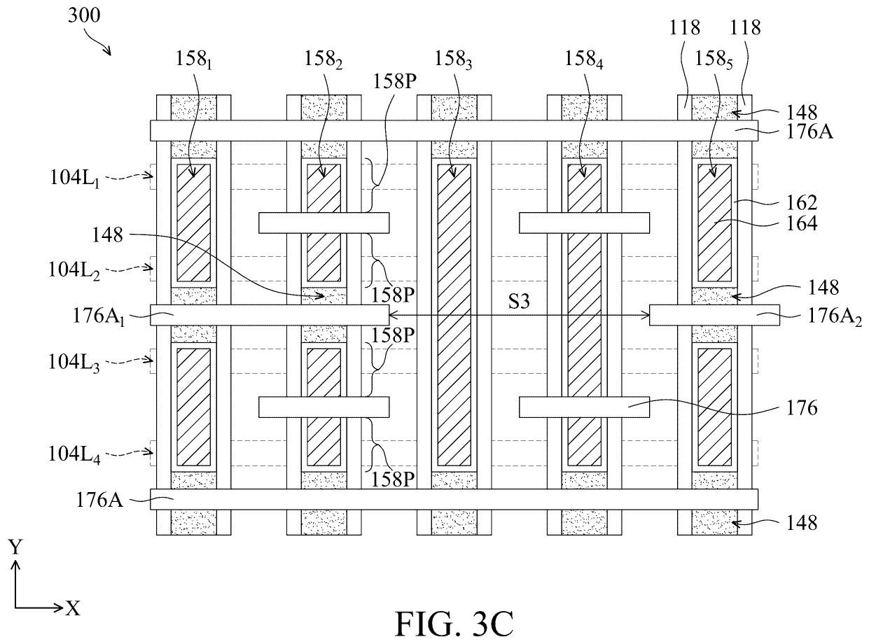

FIGS. 3A, 3B and 3C are top views illustrating the formation of a semiconductor structure 300 at various intermediate stages, in accordance with some embodiments of the disclosure. The embodiments of FIGS. 3A to 3C are similar to the embodiments of FIGS. 2A and 2B except the end-to-end distance of two neighboring trench patterns 144 is longer.

Continuing from FIG. 1B, a patterned mask layer 140 is formed over the semiconductor structure 300, as shown in FIG. 3A, in accordance with some embodiments. In some embodiments, the distance S1 between the trench patterns 144₂ and 144₄ is greater than 2 times the pitch P of the dummy gate structures 112. In some embodiments, due to the corner rounding effect, the end of the trench pattern 144₂ facing the trench pattern 144₄ may retreat onto the gate spacer layer 118 so that the portion of the dummy gate structure 112₂ between the active regions 1042 and 1043 has areas 112A that are not covered by the trench pattern 144₂, in accordance with some embodiments. In some embodiments, the areas 112A of the dummy gate structure 112₂ may be removed in the trimming process as described above in FIG. 1D.

The steps described above in FIGS. 1C to 1H-3 are performed, thereby forming wall structures 148, final gate stacks 158 and gate-cut trenches 174, as shown in FIG. 3B, in accordance with some embodiments. In some embodiments, the distance S3 between the trench patterns 172A1 and 172A2 is less than distance S1 (FIG. 3A), as shown in FIG. 3B. The steps described above in FIGS. 1I to 1I-3 are performed, thereby forming gate-cut structures 176, as shown in FIG. 3C, in accordance with some embodiments.

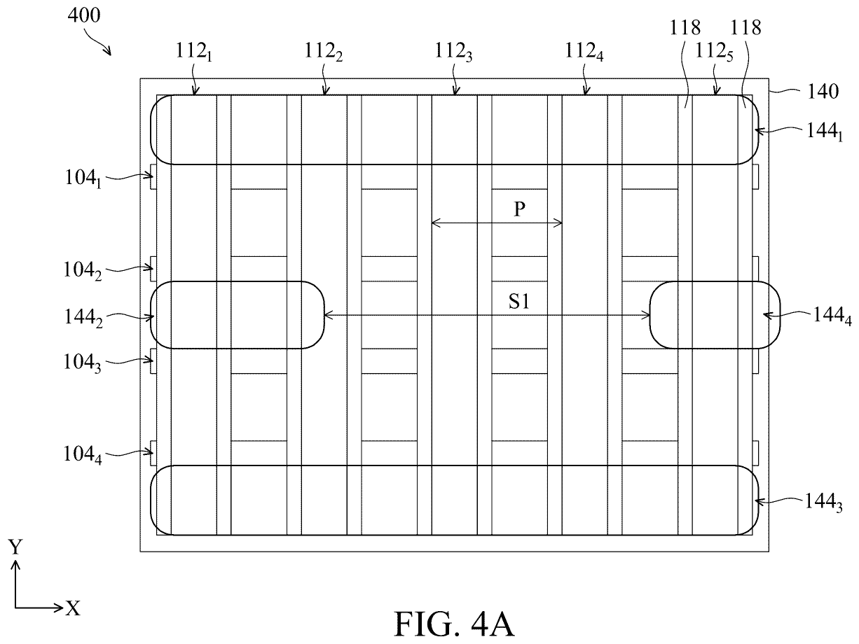

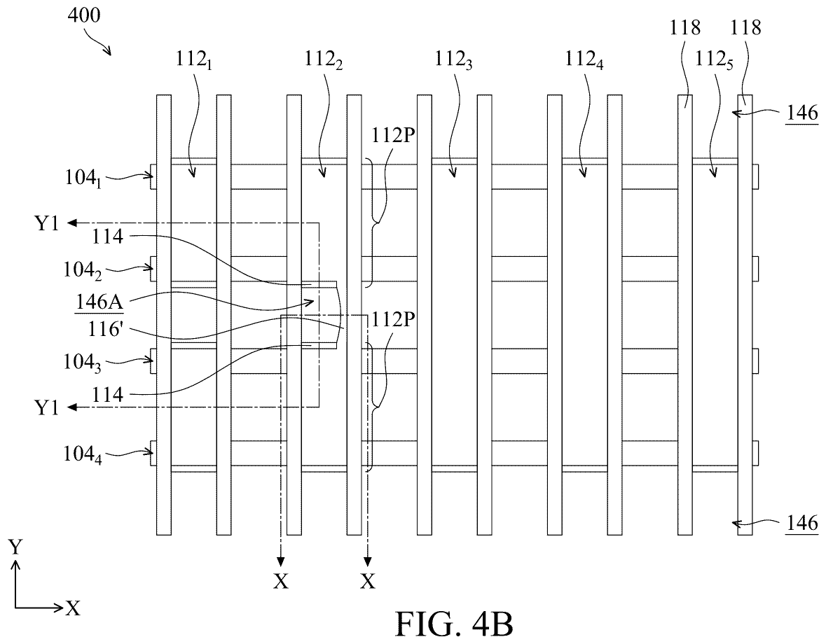

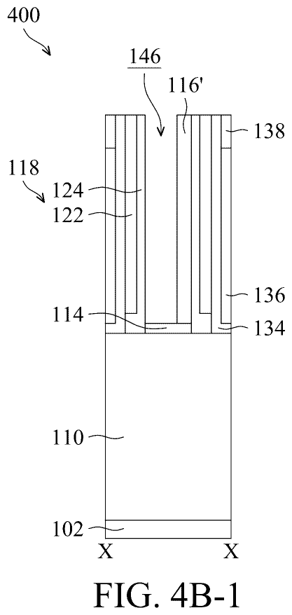

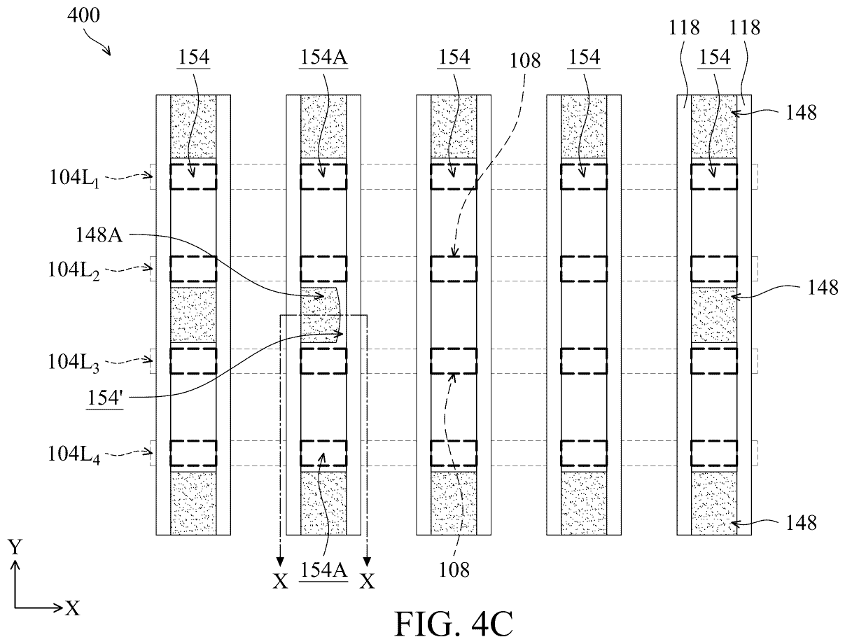

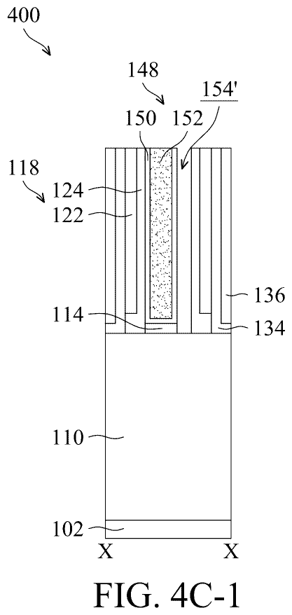

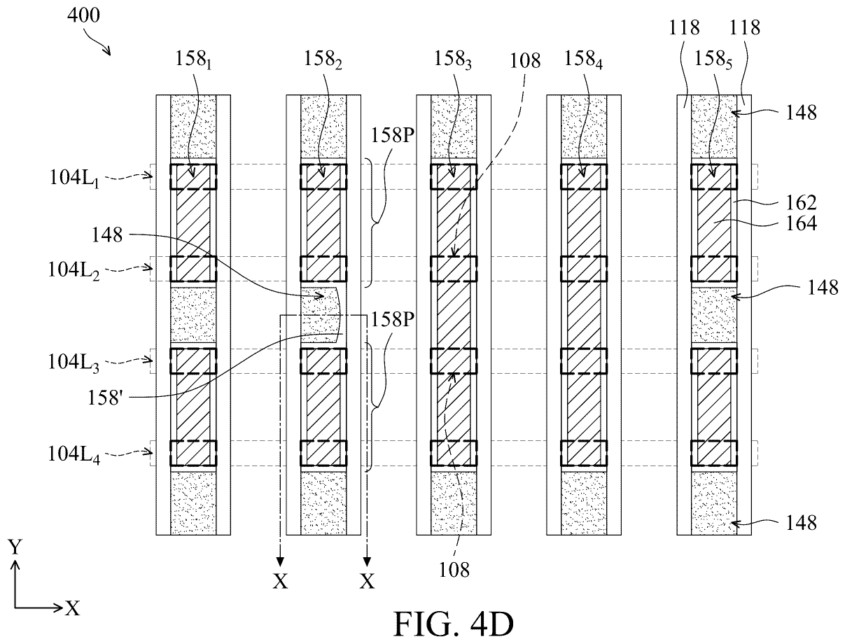

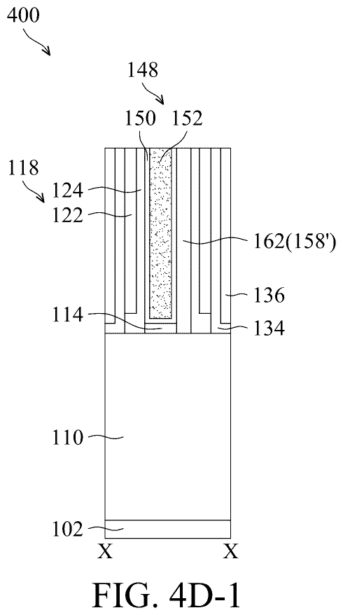

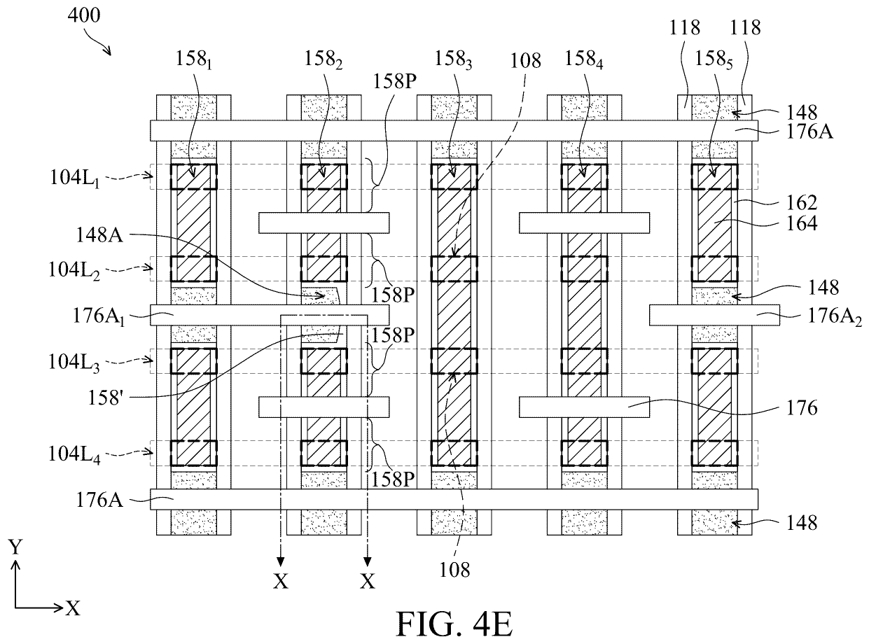

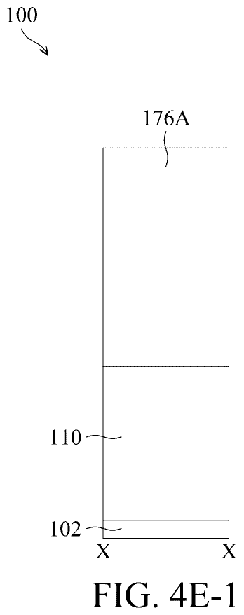

FIGS. 4A, 4B, 4C, 4D and 4E are top views illustrating the formation of a semiconductor structure 400 at various intermediate stages, in accordance with some embodiments of the disclosure. FIGS. 4B-1, 4C-1, 4D-1 and 4E-1 are cross-sectional views corresponding to line X-X of FIGS. 4B, 4C, 4D and 4E. The embodiments of FIGS. 4A to 4D-1 are similar to the embodiments of FIGS. 3A to 3C except the end-to-end distance of two neighboring trench patterns 144 is longer.

Continuing from FIG. 1B, a patterned mask layer 140 is formed over the semiconductor structure 300, as shown in FIG. 3A, in accordance with some embodiments. In some embodiments, the end of the trench pattern 144₂ facing the trench pattern 144₄ may retreat onto the dummy gate structure 112₂, in accordance with some embodiments.

The steps described above in FIGS. 1C to 1D-3 are performed, thereby forming gate-cut openings 146, as shown in FIGS. 4B and 4B-1, in accordance with some embodiments. In some embodiments, the dummy gate electrode layer 116 of the dummy gate structure 112₂ is not completely cut off by the gate-cut openings 146A, and the dummy gate segments 112P of the dummy gate structure 112₂ are connected to each other through the remaining portion 116′ of the dummy gate electrode layer 116.

The steps described above in FIGS. 1E to 1F-3 are performed, thereby forming wall structures 146, gate trenches 154 and gaps 156, as shown in FIGS. 4C and 4C-1, in accordance with some embodiments. The gate trenches 154A formed by removing the dummy gate structure 112₂ are connected to each other through a connection portion 154′, in accordance with some embodiments.

The steps described above in FIGS. 1G to 1G-3 are performed, thereby forming final gate stacks 158, as shown in FIG. 4D, in accordance with some embodiments. In some embodiments, the gate segments 158P of the final gate stacks 1582 are connected to each other through a connection portion 158′, as shown in FIGS. 4D and 4D-1. In some embodiments, the connection portion 158′ is formed by filling the gate material in the connection portion 154′ of the gate trenches 154A. In some embodiments, the connection portion 158′ is a portion of the gate dielectric layer 162. In some other embodiments, the connection portion 158′ includes a portion of the gate dielectric layer 162 and a portion of the metal gate electrode layer 164.

The steps described above in FIGS. 1H to 1I-3 are performed, thereby forming gate-cut structure 176, as shown in FIGS. 4E and 4E-1, in accordance with some embodiments. The connection portion 158′ of the final gate stacks 158 is completely cut through by the gate-cut structure 176A1, in accordance with some embodiments.

As described above, the semiconductor structure includes wall structures 148 and gate-cut structures 176, which are used to physically and electrically isolate the gate segments 158P from each other. In some embodiments, some 176A of the gate-cut structures 176 correspond to and are formed in the wall structures 148. The formation of the wall structures 148 may achieve a smaller end-cap and has a better cost advantage, while the formation of the gate-cut structure 176 may reach higher lithography limits. Therefore, the wall structures 148 and gate-cut structures 176A are combined as gat-cut features, which may a good balance between manufacturing cost and performance and reliability of the resulting semiconductor device.

Embodiments of a semiconductor structure and the method for forming the same may be provided. The method for forming the semiconductor structure may include forming a wall structure through a dummy gate structure, replacing the dummy gate structure with a gate stack, and forming a gate-cut structure through the wall structure. The wall structure may be helpful in reducing the total cell parasitic capacitance, and the gate-cut structure may ensure that the gate stack is completely cut off. Therefore, the performance and reliability of the resulting semiconductor device may be improved.

In some embodiments, a method for forming a semiconductor structure is provided. The method includes forming an isolation structure between a first active region and a second active region. The method includes forming a dummy gate structure across channel regions of the first active region and the second active region. The method includes patterning the dummy gate structure to form a cut opening corresponding to the isolation structure. The method includes forming a wall structure in the cut opening. The method includes removing the dummy gate structure to form a gate trench. The method includes forming a gate stack in the gate trench. The method includes forming a first gate-cut structure through the wall structure.

In some embodiments, a method for forming a semiconductor structure is provided. The method includes forming a plurality of dummy gate structures across a plurality of active regions. The method includes forming a first patterned mask layer over the plurality of dummy gate structures. The first patterned mask layer has a first trench pattern overlapping a first dummy gate structure and a second dummy gate structure in the plurality of dummy gate structures. The method further includes etching the first dummy gate structure and the second dummy gate structure using the first patterned mask layer to form a first cut opening and a second cut opening, respectively. The method further includes filling the first cut opening and a second cut opening with a first wall structure and the second wall structure, respectively. The method further includes replacing the plurality of dummy gate structures with a plurality of gate stacks. The method further includes forming a second patterned mask layer over the plurality of gate stacks. The second patterned mask layer has a second trench pattern, and the second trench pattern overlaps the first wall structure and the second wall structure. The method further includes etching the first wall structure and the second wall structure using the second patterned mask layer to form a first cut trench.

In some embodiments, a semiconductor structure is provided. The semiconductor structure includes first nanostructures and second nanostructures adjacent to the first nanostructures, and a gate stack extending in a first horizontal direction. The gate stack includes a first gate segment surrounding the first nanostructures and a second gate segment surrounding the second nanostructures. The semiconductor structure further includes a first wall structure interposed between the first gate segment and the second gate segment, and a first gate-cut structure penetrating the first wall structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming an isolation structure between a first active region and a second active region;
forming a dummy gate structure across channel regions of the first active region and the second active region;
patterning the dummy gate structure to form a cut opening corresponding to the isolation structure;
forming a wall structure in the cut opening;
removing the dummy gate structure to form a gate trench;
forming a gate stack in the gate trench; and
forming a first gate-cut structure through the wall structure.

2. The method for forming the semiconductor structure as claimed in claim 1, further comprising:
forming gate spacer layers on opposite sides of the dummy gate structure, wherein the cut opening is defined between the gate spacer layers.

3. The method for forming the semiconductor structure as claimed in claim 2, further comprising:
forming an interlayer dielectric layer to cover source/drain regions of the first active region and the second active region,
wherein patterning the dummy gate structure comprises forming a patterned mask layer with a trench pattern directly over the dummy gate structure, the gate spacer layers and the interlayer dielectric layer.

4. The method for forming the semiconductor structure as claimed in claim 3, wherein the first gate-cut structure further cuts through the interlayer dielectric layer and the gate spacer layers.

5. The method for forming the semiconductor structure as claimed in claim 2, wherein:
the dummy gate structure is patterned into a first dummy gate segment, a second dummy gate segment and a remaining portion between the first dummy gate segment and the second dummy gate segment,
the remaining portion of the dummy gate structure is removed to form a connection portion of the gate trench,
the connection portion of the gate trench is filled by the gate stack to form a connection portion of the gate stack, and
the first gate-cut structure further cuts through the connection portion of the gate stack.

6. The method for forming the semiconductor structure as claimed in claim 1, wherein the dummy gate structure includes a dummy gate dielectric layer and a dummy gate electrode layer over the dummy gate dielectric layer, and patterning the dummy gate structure to form the cut opening comprises:
vertically etching the dummy gate electrode layer until a first portion of the dummy gate dielectric layer on an upper surface of the isolation structure is exposed; and
after vertically etching the dummy gate electrode layer, laterally etching the dummy gate electrode layer to expose second portions of the dummy gate dielectric layer on sidewalls of the first active region and the second active region.

7. The method for forming the semiconductor structure as claimed in claim 1, wherein in a direction parallel to a longitudinal axis of the gate stack, a dimension of the wall structure is greater than a dimension of the first gate-cut structure.

8. The method for forming the semiconductor structure as claimed in claim 1, wherein the gate-cut structure extends into the isolation structure.

9. The method for forming the semiconductor structure as claimed in claim 1, further comprising:
forming a second gate-cut structure through the gate stack while forming the first gate-cut structure through the wall structure.

10. A method for forming a semiconductor structure, comprising:
forming a plurality of dummy gate structures across a plurality of active regions;
forming a first patterned mask layer over the plurality of dummy gate structures, wherein the first patterned mask layer has a first trench pattern overlapping a first dummy gate structure and a second dummy gate structure in the plurality of dummy gate structures;
etching the first dummy gate structure and the second dummy gate structure using the first patterned mask layer to form a first cut opening and a second cut opening, respectively;
filling the first cut opening and the second cut opening with a first wall structure and a second wall structure, respectively;
replacing the plurality of dummy gate structures with a plurality of gate stacks;
forming a second patterned mask layer over the plurality of gate stacks, wherein the second patterned mask layer has a second trench pattern, and the second trench pattern overlaps the first wall structure and the second wall structure; and
etching the first wall structure and the second wall structure using the second patterned mask layer to form a first cut trench.

11. The method for forming the semiconductor structure as claimed in claim 10, wherein in a direction parallel to longitudinal axes of the dummy gate structures, a dimension of the second trench pattern is less than a dimension of the first trench pattern.

12. The method for forming the semiconductor structure as claimed in claim 10, wherein:
the first patterned mask layer has a third trench pattern overlapping a third dummy gate structure in the plurality of dummy gate structures,
the first trench pattern and the third trench pattern of the first patterned mask layer are located between a first active region and a second active region in the plurality of active regions, and
a first distance between the first trench pattern and the third trench pattern is greater than 1.5 times a pitch of the dummy gate structures.

13. The method for forming the semiconductor structure as claimed in claim 12, further comprising:
etching the third dummy gate structure to form a third cut opening corresponding to the third trench pattern;
filling the third cut opening with a third wall structure,
wherein the second patterned mask layer has a fourth trench pattern overlapping the third wall structure, and
a second distance between the second trench pattern and the fourth trench pattern is less than the first distance; and
etching the third wall structure using the second patterned mask layer to form a second cut trench.

14. The method for forming the semiconductor structure as claimed in claim 10, further comprising:
forming a stack of alternating first semiconductor layers and second semiconductor layers; and
patterning the stack to form the plurality of active regions.

15. A semiconductor structure, comprising:
first nanostructures and second nanostructures adjacent to the first nanostructures;
a gate stack extending in a first horizontal direction and including a first gate segment surrounding the first nanostructures and a second gate segment surrounding the second nanostructures;
a first wall structure interposed between the first gate segment and the second gate segment; and
a first gate-cut structure penetrating the first wall structure.

16. The semiconductor structure as claimed in claim 15, further comprising:
a first fin element below the first nanostructures and extending in a second horizontal direction perpendicular to the first horizontal direction;
a second fin element below the second nanostructures and extending in the second horizontal direction; and
an isolation structure surrounding the first fin element and the second fin element, wherein the first gate-cut structure includes a portion embedded in the isolation structure.

17. The semiconductor structure as claimed in claim 15, wherein in the first horizontal direction, a dimension of the first wall structure is greater than a dimension of the first gate-cut structure.

18. The semiconductor structure as claimed in claim 15, further comprising:
third nanostructures adjacent to the second nanostructures, wherein the gate stack includes a third gate segment surrounding the third nanostructures; and
a second gate-cut structure interposed between the second gate segment and the third gate segment.

19. The semiconductor structure as claimed in claim 15, wherein:
the first wall structure includes a dielectric bulk layer and a plurality of dielectric lining layers on the dielectric bulk layer, and
the gate stack includes a gate dielectric layer and a gate electrode layer over the gate dielectric layer, wherein the gate dielectric layer is in direct contact with the plurality of dielectric lining layers and the dielectric bulk layer.

20. The semiconductor structure as claimed in claim 15, further comprising:
third nanostructures and fourth nanostructures adjacent to the third nanostructures;
a first fin element below the first nanostructures and the third nanostructures;
a second fin element below the second nanostructures and the fourth nanostructures;
a second gate stack extending in the first horizontal direction and including a third gate segment surrounding the third nanostructures and a fourth gate segment surrounding the fourth nanostructures;
a second wall structure interposed between the third gate segment and the fourth gate segments; and
a second gate-cut structure penetrating the second wall structure,
wherein a distance between the first wall structure and the second wall structure is greater than a distance between the first gate-cut structure and the second gate-cut structure.
